(19) United States
(12) Patent Application Publication
(10) Pub. No.: US 2025/0323086 A1
(43) Pub. Date: Oct. 16, 2025

(54) IMPROVED PEDESTALS FOR SUBSTRATE PROCESSING SYSTEMS

(71) Applicant: LAM RESEARCH CORPORATION, Fremont, CA (US)

(72) Inventors: Krishna BIRRU, Fremont, CA (US); Leonard KHO, San Francisco, CA (US); Shreesha Yogish RAO, Fremont, CA (US); Vinayakaraddy GULABAL, Yadgir (IN); Vijay KOTHAPALLI, Fremont, CA (US); Xitong CHEN, Fremont, CA (US)

(21) Appl. No.: 18/881,608

(22) PCT Filed: Jul. 7, 2023
(86) PCT No.: PCT/US2023/027063

§ 371 Date: Jan. 6, 2025

Related U.S. Application Data
(60) Provisional application No. 63/359,474, filed on Jul. 8, 2022.

(51) Int. Cl. H01L 21/687; H01L 21/683

(52) U.S. Cl. CPC H01L 21/68785; H01L 21/6833

(57) ABSTRACT

A substrate support includes at least three pockets defined along a perimeter of the substrate support, an edge gas groove located on a top surface of the substrate support, and a first clamping groove located radially inward from the edge gas groove on the top surface of the substrate support. Each pocket comprises a narrow portion and a wide portion located radially outward from the narrow portion. The edge gas groove is concentric with the substrate support. The edge gas groove intersects the narrow portion of each pocket. At least thirty through holes are within the edge gas groove and at least one through hole is within the narrow portion of each pocket.

### CROSS-REFERENCE TO RELATED APPLICATIONS

This application claims the benefit of U.S. Provisional Application No. 63,359,474, filed on Jul. 8, 2022. The entire disclosure of the application referenced above is incorporated herein by reference.

### FIELD

The present disclosure relates generally to substrate processing systems and more particularly to pedestals for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of substrates such as semiconductor wafers, etch processes and deposition processes may be performed within a processing chamber. The substrate is disposed in the processing chamber on a substrate support such as an electrostatic chuck (ESC) or a pedestal. Process gases are introduced and, in some examples, plasma is struck in the processing chamber.

Some substrate supports may comprise components such as a shadow ring or a carrier ring. For example, the shadow ring may be used to protect outer edges of the substrate from deposition and etching. The shadow ring may be raised to facilitate transfer of the substrate to the substrate support and then lowered. An inner diameter of the shadow ring overlaps the outer edge of the substrate. Conversely, a carrier ring may be used to raise and lower the substrate to facilitate transfer.

### SUMMARY

A substrate support for a substrate processing system comprises a baseplate, at least one pocket defined in a first surface of the baseplate, the at least one pocket comprising a recess configured to receive at least a portion of a carrier ring disposed on the first surface of the baseplate, a first channel routed through the baseplate and arranged to supply a process gas mixture comprising at least a first process gas and a second process gas to a backside edge of a substrate disposed on the substrate support, and a second channel routed through the baseplate and arranged to supply, separate from the first channel, one of the first process gas and the second process gas to the at least one pocket defined in the first surface of the baseplate.

In other features, the substrate support further comprises the carrier ring. The carrier ring comprises at least one contact finger that extends downward and radially inward from the carrier ring and the contact finger extends into the at least one pocket when the carrier ring is in a lowered position. The at least one pocket comprises three pockets. The substrate support further comprises an annular plenum defined in the baseplate radially inward of the at least one pocket, the second channel is in fluid communication with the annular plenum, and the annular plenum is in fluid communication with the at least one pocket. The substrate support further comprises at least one outlet channel that extends from the annular plenum to the at least one pocket. The at least one outlet channel extends upward and radially outward from the annular plenum toward the at least one pocket.

In other features, the second channel extends below the at least one pocket and at least one outlet channel extends upward from the second channel toward the at least one pocket. The second channel is disposed above the first channel in the baseplate. The second channel is disposed below the first channel in the baseplate. The substrate support further comprises a third channel routed through the baseplate and arranged to supply, separate from the first channel and the second channel, one of the first process gas and the second process gas to the at least one pocket defined in the first surface of the baseplate. The second channel is disposed above the first channel in the baseplate and the third channel is disposed below the first channel in the baseplate.

In other features, the substrate support further comprises an annular plenum defined in the baseplate radially inward of the at least one pocket, the second channel is in fluid communication with the annular plenum, and the annular plenum is in fluid communication with the at least one pocket via at least one first outlet channel. The third channel extends below the at least one pocket. At least one second outlet channel extends upward from the third channel toward the at least one pocket.

A system to supply process gases to a backside edge of a substrate disposed on a substrate support comprises a gas delivery system to supply the process gases from a plurality of gas sources to the backside edge of the substrate and a controller to control the gas delivery system to supply a process gas mixture comprising at least a first process gas and a second process gas to the backside edge via a first channel routed through the substrate support and supply one of the first process gas and the second process gas to a pocket defined in the substrate support via a second channel, separate from the first channel, routed through the substrate support.

In other features, the process gas mixture comprises argon and ammonia. The controller supplies one of the first process gas and the second process gas to the pocket via a third channel, separate from the first channel and the second channel, routed through the substrate support.

A substrate support for a substrate processing system comprises a baseplate, at least one clamping groove defined in a first surface of the baseplate, at least one pocket defined in the first surface of the baseplate, the at least one pocket comprising a recess configured to receive at least a portion of a carrier ring disposed on the first surface of the baseplate, a first channel routed through the baseplate and arranged to supply, from a first plenum, a process gas mixture comprising at least a first process gas and a second process gas to a backside edge of a substrate disposed on the substrate support and to the at least one pocket, and a second channel routed through the baseplate and arranged to supply, separate from the first channel and from a second plenum located radially inward of the first plenum and radially outward of the at least one clamping groove, one of the first process gas and the second process gas to a backside edge of the substrate.

In other features, the substrate support further comprises a third channel routed through the baseplate and arranged to supply one of the first process gas and the second process gas to the at least one pocket defined in the first surface of the baseplate. The substrate support further comprises a recess defined in the first surface of the substrate support between the first channel and the second channel. The recess provides fluid communication between the first channel and the second channel at the first surface.

A method to supply process gases to a backside edge of a substrate disposed on a substrate support comprises supplying a process gas mixture comprising at least a first process gas and a second process gas to the backside edge via a first channel routed through the substrate support and supplying one of the first process gas and the second process gas to a pocket defined in the substrate support via a second channel, separate from the first channel, routed through the substrate support.

In other features, the process gas mixture comprises argon and ammonia. The method further comprises supplying one of the first process gas and the second process gas to the pocket via a third channel, separate from the first channel and the second channel, routed through the substrate support.

In still other features, a substrate support comprises a base portion and a stem portion. The base portion comprises a plurality of plates defining a plurality of plenums in the base portion. The stem portion is coupled to the base portion. The stem portion comprises a plurality of conduits in fluid communication with the plurality of plenums.

In additional features, the base portion and the stem portion comprise a metallic material and are cylindrical. The stem portion is of a smaller diameter than the base portion.

In additional features, the plurality of plenums is configured to supply one or more gases through a top plate of the base portion and to clamp a substrate to the top plate using vacuum clamping during processing.

In additional features, a first plate of the plurality of plates is disposed between second and third plates of the plurality of plates to separate first and second plenums of the plurality of plenums defined by the first, second, and third plates.

In additional features, the first plenum is configured to supply one or more gases through a top plate of the plurality of plates around edges of a substrate disposed on the top plate during processing. The second plenum is configured to supply one or more gases to a plurality of pockets extending radially outwards from a periphery of the base portion.

In additional features, a third plenum of the plurality of plenums is configured to supply a gas through the top plate radially outwardly from under the substrate during processing.

In additional features, the supply of the one or more gases through the first and second plenums is controlled by respective mass flow controllers. The supply of the gas through the third plenum is controlled using a pressure controller.

In additional features, each plenum in the plurality of plenums is disjoint from others of the plurality of plenums. The plurality of conduits is in fluid communication with the plurality of plenums, respectively.

In additional features, the base portion comprises a plurality of pockets extending radially outwards from a periphery of the base portion. A top plate of the plurality of plates comprises a plurality of through holes in fluid communication with the plurality of pockets, respectively. The plurality of through holes extends through the top plate radially outwardly at an acute angle relative to an axis perpendicular to the base portion.

In additional features, the top plate comprises a plurality of concentric grooves. The plurality of plenums comprises first, second, and third plenums in fluid communication with the plurality of concentric grooves, respectively. The plurality of plenums comprises a fourth plenum in fluid communication with the plurality of through holes. The first, second, third, and fourth plenums are disjoint.

In additional features, the top plate comprises a plurality of concentric grooves. The plurality of plenums comprises first, second, and third plenums in fluid communication with the plurality of concentric grooves, respectively. The first, second, and third plenums are disjoint. One of the first, second, and third plenums is in fluid communication with the plurality of through holes and one of the plurality of concentric grooves.

In additional features, the base portion comprises a plurality of pockets extending radially outwards from a periphery of the base portion.

In additional features, a top plate of the plurality of plates comprises a plurality of concentric grooves. The plurality of concentric grooves is in fluid communication with the plurality of plenums in the base portion, respectively. One of the plurality of concentric grooves intersects the plurality of pockets proximate to radially inner ends of the plurality of pockets.

In additional features, the plurality of concentric grooves comprises a first concentric groove of a first diameter, a second concentric groove of a second diameter that is less than the first diameter, and a third concentric groove of a third diameter that is less than the second diameter. The first diameter is greater than a fourth diameter of the substrate. The second diameter and the third diameter are less than the fourth diameter of the substrate.

In additional features, the top plate of the plurality of plates further comprises a plurality of through holes in fluid communication with the plurality of pockets, respectively. The plurality of through holes extends through the top plate radially outwardly at an acute angle relative to an axis perpendicular to the base portion.

In additional features, the plurality of plenums comprises first, second, and third plenums in fluid communication with the plurality of concentric grooves, respectively. A fourth plenum of the plurality of plenums is in fluid communication with the plurality of through holes. The first, second, third, and fourth plenums are disjoint and are in fluid communication with the plurality of conduits, respectively.

In additional features, the fourth plenum is configured to supply a heated gas to the plurality of through holes.

In additional features, the plurality of plenums comprises first, second, and third plenums in fluid communication with the plurality of concentric grooves, respectively. The first, second, and third plenums are disjoint and are in fluid communication with the plurality of conduits, respectively. The first plenum is in fluid communication with the plurality of through holes and one of the plurality of concentric grooves.

In additional features, a top plate of the plurality of plates comprises a plurality of concentric grooves. The plurality of concentric grooves is in fluid communication with the plurality of plenums in the base portion, respectively. One of the plurality of concentric grooves intersects the plurality of pockets proximate to radially inner ends of the plurality of pockets.

In additional features, the plurality of concentric grooves comprises a first concentric groove of a first diameter and a second concentric groove of a second diameter that is less than the first diameter. The first diameter is greater than a third diameter of the substrate. The second diameter is less than the third diameter of the substrate.

In additional features, the top plate of the plurality of plates further comprises a plurality of through holes in fluid communication with the plurality of pockets, respectively. The plurality of through holes extends through the top plate radially outwardly at an acute angle relative to an axis perpendicular to the base portion.

In additional features, the plurality of plenums comprises first and second plenums in fluid communication with the plurality of concentric grooves, respectively, The plurality of plenums comprises a third plenum in fluid communication with the plurality of through holes. The first, second, and third plenums are disjoint and are in fluid communication with the plurality of conduits, respectively.

In additional features, the plurality of plenums comprises first and second plenums in fluid communication with the plurality of concentric grooves, respectively. The first plenum is in fluid communication with the plurality of through holes and the first concentric groove. The first and second plenums are disjoint and are in fluid communication with the plurality of conduits, respectively.

In additional features, the plurality of plates comprises a first plate coupled to the stem portion. A second plate has a first surface bonded to the first plate. The second plate comprises a circular slot in a second surface. A third plate is bonded to the second surface of the second plate. A fourth plate is bonded to the third plate. A fifth plate is disposed in the circular slot and is bonded to the second plate and the third plate. The second plate comprises a first plenum of the plurality of plenums defined by a first annular groove and a first set of radial grooves extending radially inwards from the first annular groove and connecting to a first conduit of the plurality of conduits. The third plate comprises, on a first surface bonded to the fifth plate, a second plenum of the plurality of plenums defined by a second set of grooves extending radially inwards from a first set of through holes and connecting to a second conduit of the plurality of conduits. A diameter of the fifth plate is equal to an inner diameter of the first annular groove. The diameter of the fifth plate is greater than a diameter of a circle on which the first set of through holes lies.

In additional features, the third plate comprises, on a second surface bonded to the fourth plate, a third plenum of the plurality of plenums defined by a second annular groove, a third set of grooves extending radially outwards from the second annular groove, and a fourth set of grooves extending radially inwards from the second annular groove and connecting to a third conduit of the plurality of conduits.

In additional features, the fourth plate comprises a first groove and a second groove. The first and second grooves are concentric. The first groove is greater in diameter than the second groove and greater in diameter than a substrate supported on the substrate support. The third and fourth plates comprise a second set of through holes in fluid communication with the first plenum and with the first groove. The fourth plate comprises a third set of through holes extending radially outwardly at an acute angle relative to an axis perpendicular to the base portion. The third set of through holes is in fluid communication with the second plenum. The fourth plate comprises a fourth set of through holes in fluid communication with the third set of grooves, the second groove, and with the third plenum.

In additional features, the base portion comprises a plurality of pockets extending radially outwards from a periphery of the base portion. The third set of through holes is in fluid communication with the plurality of pockets, respectively. The first groove intersects the plurality of pockets proximate to radially inner ends of the plurality of pockets.

In additional features, the plurality of plates comprises a first plate coupled to the stem portion, a second plate bonded to the first plate, and a third plate bonded to the second plate. The second plate comprises a first plenum of the plurality of plenums defined by an annular groove and a set of radial grooves extending radially inwards from the annular groove and connecting to a first conduit of the plurality of conduits. The third plate comprises a circular groove and a set of through holes in fluid communication with the first plenum.

In additional features, the base portion comprises a plurality of pockets extending radially outwards from a periphery of the base portion. The circular groove intersects the plurality of pockets proximate to radially inner ends of the plurality of pockets. A diameter of the circular groove is greater than a diameter of the substrate supported on the third plate.

In additional features, a top plate of the plurality of plates comprises a plurality of clamping grooves. One of the plurality of plenums is in fluid communication with the plurality of clamping grooves and with one of the plurality of conduits. The plurality of clamping grooves is configured to clamp a substrate to the top plate using vacuum.

In additional features, the plurality of clamping grooves comprises concentric grooves and radial grooves connected to the concentric grooves. A depth of at least one of the concentric grooves and the radial grooves is greater than a width of the at least one of the concentric grooves and the radial grooves.

In additional features, the top plate comprises a plurality through holes arranged in a plurality of the radial grooves in a plurality of concentric circles.

In additional features, edges of at least one of the concentric grooves and the radial grooves are rounded.

In additional features, a top plate of the plurality of plates comprises a first groove and a second groove in fluid communication with first and second plenums of the plurality of plenums. The first and second grooves are concentric. The first groove is greater in diameter than the second groove and greater in diameter than a substrate. The base portion comprises a plurality of pockets extending radially outwards from a periphery of the base portion. The first groove intersects the plurality of pockets proximate to radially inner ends of the plurality of pockets. An inner diameter of the first groove is closer to the radially inner ends of the plurality of pockets than to the second groove.

In additional features, the base portion comprises a plurality of pockets extending radially outwards from a periphery of the base portion. Each of the plurality of pockets comprises a slot in an outer wall. The slot is located away from bonding interfaces between the plurality of plates.

In additional features, a height of the slot is less than a thickness of one of the plurality of plates in which the slot is located.

In additional features, the substrate support further comprises a heater coil disposed in one of the plurality of plates. The heater coil comprises at least three turns uniformly distributed from a center of the base portion to an outer diameter of the base portion.

In additional features, the substrate support further comprises a heater coil disposed in the base portion. The heater coil is connected to a power supply by a pair of insulated conductors disposed through the stem portion. A temperature sensor is disposed in the base portion. The temperature sensor is connected to circuitry via an additional conduit disposed through the stem portion. The plurality of conduits, the pair of conductors, and the additional conduit pass through an opening in the stem portion.

In still other features, a substrate support comprises at least three pockets defined along a perimeter of the substrate support, an edge gas groove located on a top surface of the substrate support, and a first clamping groove located radially inward from the edge gas groove on the top surface of the substrate support. Each pocket comprises a narrow portion and a wide portion located radially outward from the narrow portion. The edge gas groove is concentric with the substrate support. The edge gas groove intersects the narrow portion of each pocket. At least thirty through holes are within the edge gas groove and at least one through hole is within the narrow portion of each pocket.

In additional features, the substrate support further comprises at least one angular hole located within the narrow portion of at least one of the at least three pockets, and a purge gas groove located between the edge gas groove and the first clamping groove on the top surface of the substrate support. The at least one angular hole is connected to a gas delivery conduit.

In additional features, the edge gas groove, the purge gas groove, and the first clamping groove are concentric.

In additional features, for the at least one of the at least three pockets, the angular hole is located on a radially inner sidewall of the narrow portion of the respective pocket, the radially inner sidewall of the narrow portion is a closest pocket surface to a center of the substrate support.

In additional features, the radially inner sidewall is perpendicular to a bottom surface of the respective pocket.

In additional features, the angular hole is located above at least 25% of a height of the radially inner sidewall of the narrow portion of the respective pocket, where the height is measured from a bottom surface of the respective pocket.

In additional features, the angular hole is located above at least 50-75% of a height of the radially inner sidewall of the narrow portion of the pocket.

In additional features, the gas delivery conduit has a center axis that is not perpendicular to the radially inner sidewall of the narrow portion of the respective pocket.

In additional features, a center axis of the gas delivery conduit forms an acute angle with the radially inner sidewall of the narrow portion of the pocket.

In additional features, the acute angle is between 20 to 80 degrees.

In additional features, the acute angle is between 30 to 70 degrees.

In additional features, the acute angle is between 40 to 60 degrees.

In additional features, the purge gas groove includes one or more through holes.

In additional features, the purge gas groove and the first clamping groove comprise inward rounded portions radially aligned with inner ends of the respective pockets.

In additional features, the substrate support further comprises a plurality of clamping grooves located radially inward from the first clamping groove. The plurality of clamping grooves comprises a plurality of radial clamping grooves and one or more concentric clamping grooves. At least one of the plurality of radial clamping grooves intersects with at least one concentric clamping grooves and the first clamping groove.

In additional features, the plurality of radial clamping grooves proximate to a center portion of the substrate support comprises a plurality through holes arranged in a circular arrangement.

In additional features, the plurality of radial clamping grooves proximate to a center portion of the substrate support comprises one or more through holes along each of the plurality of radial clamping grooves.

In additional features, a diameter of the one or more through holes occupies between 55-90% of a width of the respective radial clamping groove.

In additional features, at least one of the three pockets is defined in an ear potion of the substrate support. The ear portion of the substrate support includes a slot that is defined on an outer surface of the ear portion. The slot is wholly defined within a single plate.

In additional features, the substrate support further comprises a plurality of ceramic springs disposed on the top surface of the substrate support.

In additional features, the substrate support further comprises a plurality of clamping grooves located radially inward from the first clamping groove. The plurality of clamping grooves comprises a plurality of radial clamping grooves and one or more concentric clamping grooves. At least one of the plurality of radial clamping grooves intersects with the one or more concentric clamping grooves and the first clamping groove.

In additional features, the plurality of radial clamping grooves proximate to a center portion of the substrate support comprises a plurality through holes arranged in a circular arrangement.

In additional features, the plurality of radial clamping grooves proximate to a center portion of the substrate support comprises one or more through holes along each of the plurality of radial clamping grooves.

In additional features, a diameter of the one or more through holes occupies between 55-90% of a width of the respective radial clamping groove.

In additional features, at least one of the three pockets is defined in an ear potion of the substrate support. The ear portion of the substrate support includes a slot that is defined on an outer surface of the ear portion. The slot is wholly defined within a single plate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system comprising an example carrier ring according to the present disclosure;

FIG. 2A is a first example substrate support according to the present disclosure;

FIG. 2B is a second example substrate support according to the present disclosure;

FIG. 2C is a plan view of the first example substrate support of FIG. 2A;

FIG. 2D is a third example substrate support according to the present disclosure;

FIG. 2E is a fourth example substrate support according to the present disclosure;

FIG. 2F is a fifth example substrate support according to the present disclosure;

FIG. 2G is a sixth example substrate support according to the present disclosure;

FIG. 3 illustrate steps of an example method of supplying gas mixtures to a backside edge of a substrate arranged on a substrate support according to the present disclosure;

FIG. 4A shows a perspective view of an example of a substrate support comprising multiple plates that define various plenums in the substrate support according to the present disclosure;

FIGS. 4B and 4C show exploded views of the substrate support comprising of FIG. 4A according to the present disclosure;

FIG. 5 shows a cross-sectional view of the substrate support of FIG. 4A according to the present disclosure;

FIGS. 6A-6C show top and bottom views of a top plate of the substrate support of FIG. 4A according to the present disclosure;

FIG. 7 shows a top view of a second plate (counted from bottom) of the substrate support of FIG. 4A according to the present disclosure;

FIGS. 8 and 9 show top and bottom views of a third plate (counted from bottom) of the substrate support of FIG. 4A according to the present disclosure;

FIG. 10 shows top and bottom views of an additional plate disposed between the second and third plates (counted from bottom) of the substrate support of FIG. 4A according to the present disclosure;

FIGS. 11A-11E show examples of clamping grooves on the top plate of the substrate support of FIG. 4A, which are shown in FIG. 6A, in further detail according to the present disclosure;

FIG. 12 shows spatial relationships of edge gas and purge gas grooves on the top plate of the substrate support of FIG. 4A relative to pockets located on a periphery of the substrate support of FIG. 4A according to the present disclosure;

FIG. 13 shows a cross-sectional view of another example of a substrate support according to the present disclosure;

FIGS. 14A and 14B show a top view of a top plate of the substrate support of FIG. 13 according to the present disclosure;

FIGS. 15 and 16 show cross-sectional views of additional examples of substrate supports according to the present disclosure;

FIG. 17 shows a top view of top plates of the substrate supports of FIGS. 15 and 16 according to the present disclosure;

FIGS. 18 and 19 show cross-sectional views of additional examples of substrate supports according to the present disclosure;

FIGS. 20A and 20B show side views of pockets of the pedestals of the present disclosure in further detail;

FIGS. 21A and 21B show examples of heater coils for the pedestals of the present disclosure;

FIGS. 22A and 22B show an example of a carrier ring and substrate holder assembly according to the present disclosure;

FIGS. 23A-25B show cross-sectional and perspective views of stem portions of the pedestals showing arrangements of various conduits in the stem portions of the pedestals of the present disclosure;

FIG. 26 shows an example of a substrate processing system for processing substrates using the pedestals of the present disclosure;

FIG. 27 shows a top view of the pocket of the pedestal; and

FIG. 28 shows an expanded view of an angular hole in the pocket of the pedestal.

In the drawings, reference numbers may be reused to identify similar and/or identical elements.

### DETAILED DESCRIPTION

In substrate processing systems that use a component such as a shadow ring, a carrier ring, a combined shadow/carrier ring, etc., a substrate support may comprise various features configured to facilitate interfacing or alignment between the component and the substrate support. For example, a first (upper) surface of the substrate support may comprise one or more recesses or pockets (e.g., defined with a ceramic layer, baseplate, etc.). In some examples, the pockets are configured to accommodate features of a carrier ring in a lowered position. For example, the pockets may correspond to substrate pickup locations of the carrier ring (e.g., locations of fingers on the carrier ring configured to pick up the substrate). In other examples, the pockets comprise alignment features for aligning a shadow ring, a carrier ring, and/or another component to the substrate support.

In some instances, the pockets may cause process nonuniformities. For example, deposition thickness on a substrate may be reduced at locations corresponding to the pockets. In some examples, the pockets disrupt flow of process gases including purge gases (e.g., argon, ammonia (NH₃), etc.) at an edge of the substrate. The substrate support may be configured to supply process gases including purge gases to a backside edge of the substrate to improve deposition uniformity. However, the pockets still disrupt flow of the process gases and cause deposition nonuniformities. For example, supplying the deposition process gases to the backside edge of the substrate may increase deposition at locations corresponding to the pockets but cause deposition nonuniformities at other locations along the edge of the substrate.

A substrate support according to the present disclosure comprises two or more channels configured to supply dedicated flows of different process gases or process gas mixtures including purge gases to the pockets. For example, the substrate support may comprise multiple, separate plenums and/or channels. In one example, a first channel supplies a process gas mixture comprising multiple process gases (e.g., argon and ammonia) including purge gases to a backside edge of the substrate. A second channel supplies only one of the process gases (e.g., argon) to the pockets. In some examples, a third channel supplies (separate from the second channel) the other of the process gases (e.g., ammonia) to the pockets. In this manner, supply of a process gas mixture and individual process gases in the process gas mixture including purge gases to different regions of the backside edge of the substrate can be separately controlled.

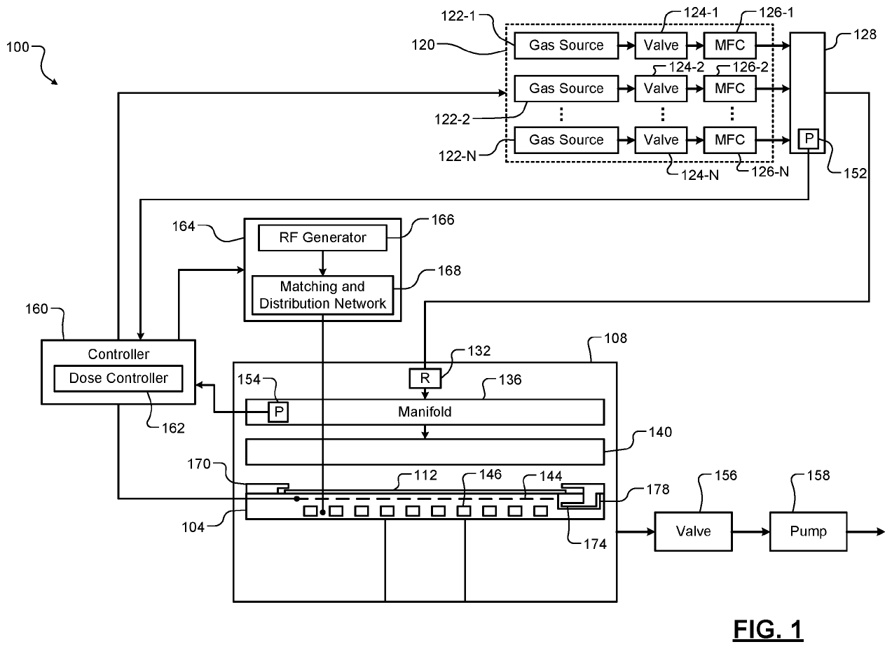

Referring now to FIG. 1, an example of a substrate processing system 100 comprising a substrate support (e.g., a pedestal configured for CVD and/or ALD deposition) 104 according to the present disclosure is shown. The substrate support 104 is arranged within a processing chamber 108. A substrate 112 is arranged on the substrate support 104 during processing. For example, deposition is performed on the substrate 112. The substrate 112 is removed and one or more additional substrates are treated.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a manifold 136. An output of the manifold 136 is input to a gas distribution device such as a multi-injector showerhead 140. While the manifold 128 and 136 are shown, a single manifold can be used.

In some examples, a temperature of the substrate support 104 may be controlled using resistive heaters 144. Pressure sensors 152, 154 may be arranged in the manifold 128 or the manifold 136, respectively, to measure pressure. A valve 156 and a pump 158 may be used to evacuate reactants from the processing chamber 108 and/or to control pressure within the processing chamber 108.

A controller 160 comprises a dose controller 162 that controls dosing provided by the multi-injector showerhead 140. The controller 160 also controls gas delivery from the gas delivery system 120. The controller 160 controls pressure in the processing chamber and/or evacuation of reactants using the valve 156 and the pump 158. The controller 160 controls the temperature of the substrate support 104 and the substrate 112 based upon temperature feedback (e.g., from sensors (not shown) in the substrate support and/or sensors (not shown) measuring coolant temperature).

Although described as being configured to perform deposition processes, the substrate processing system 100 may be configured to perform etching processes. In some examples, the substrate processing system 100 may be configured to perform etching on the substrate 112 within the same processing chamber 108 as deposition processes. Accordingly, the substrate processing system 100 may comprise an RF generating system 164 configured to generate and provide RF power (e.g., as a voltage source, current source, etc.) to one of a lower electrode (e.g., a baseplate of the substrate support 104, as shown) and an upper electrode (e.g., the showerhead 140). The other one of the lower electrode and the upper electrode may be DC grounded, AC grounded or floating.

For example only, the RF generating system 164 may comprise an RF generator 166 configured to generate the RF voltage that is fed by a matching and distribution network 168 to generate plasma within the processing chamber 108 to etch the substrate 112. In other examples, the plasma may be generated inductively or remotely. Although, as shown for example purposes, the RF generating system 164 corresponds to a capacitively coupled plasma (CCP) system, the principles of the present disclosure may also be implemented in other suitable systems, such as, for example only, transformer coupled plasma (TCP) systems, CCP cathode systems, remote microwave plasma generation and delivery systems, etc.

The substrate support 104 comprises a carrier ring 170. In some examples, an inner edge of the carrier ring 170 overlaps an outer edge of the substrate 112. The carrier ring 170 may be raised and lowered (e.g., using lift pins and respective actuators, not shown in FIG. 1). For example, the carrier ring 170 comprises one or more (e.g., three uniformly spaced) contact fingers 174 extending downward from the carrier ring 170 and radially inward toward the substrate 112.

As shown, the carrier ring 170 is in a lowered position. In the lowered position, the contact fingers 174 are disposed within corresponding pockets 178 defined in an upper surface of the substrate support 104. When moved to a raised position, the contact fingers 174 engage the outer edge of the substrate 112 to raise the substrate 112 to facilitate transfer. Conversely, when the carrier ring 170 is in the raised position, the substrate 112 is transferred to the contact fingers 174. The carrier ring 170 is then lowered to lower the substrate 112 onto the substrate support 104.

The substrate support 104 according to the present disclosure comprises two or more channels configured to supply dedicated flows of different deposition process gases or process gas mixtures to the pockets 178 as described below in more detail.

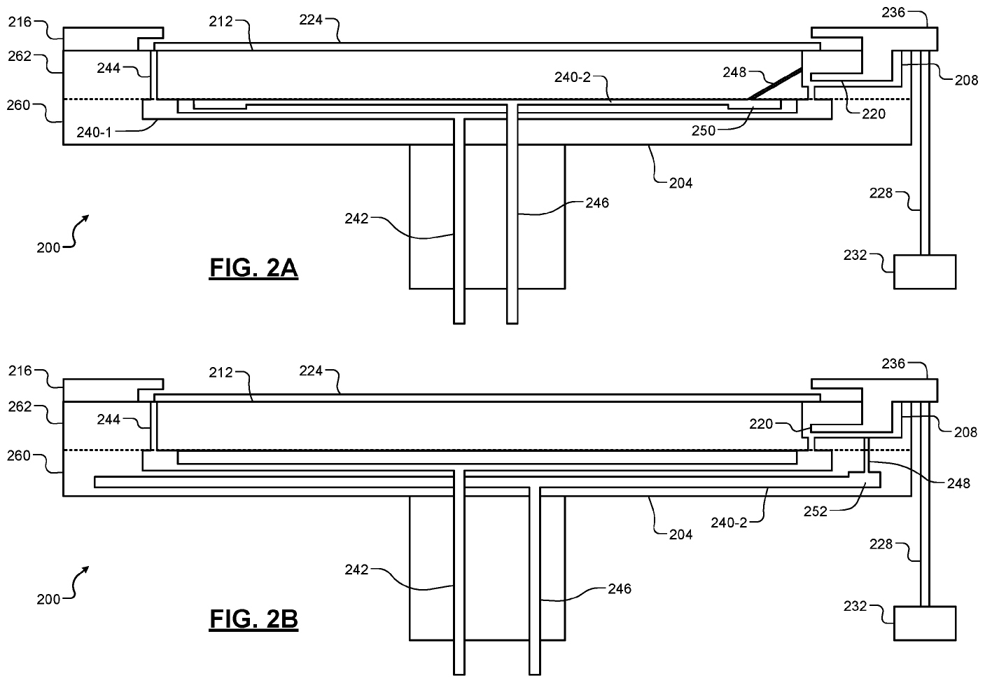

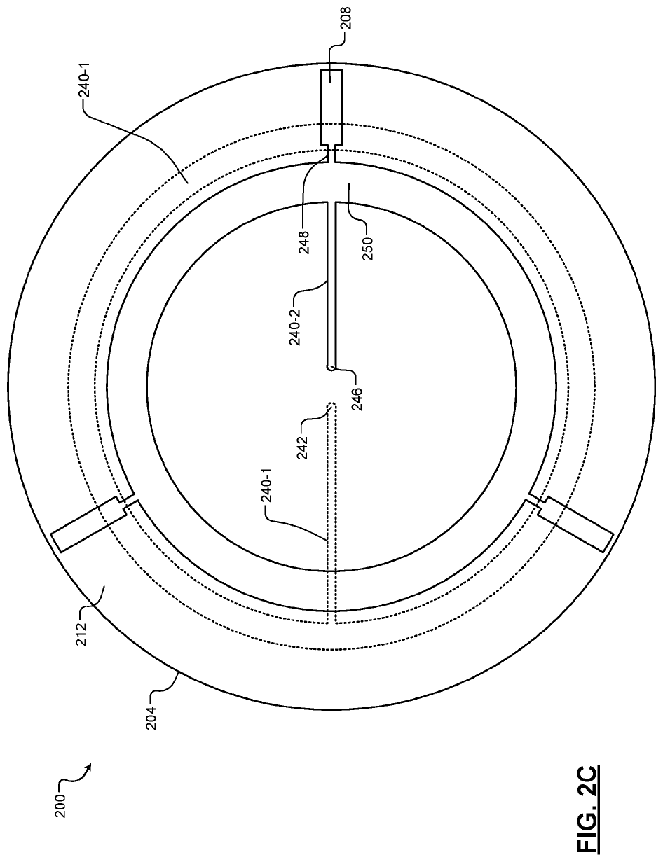

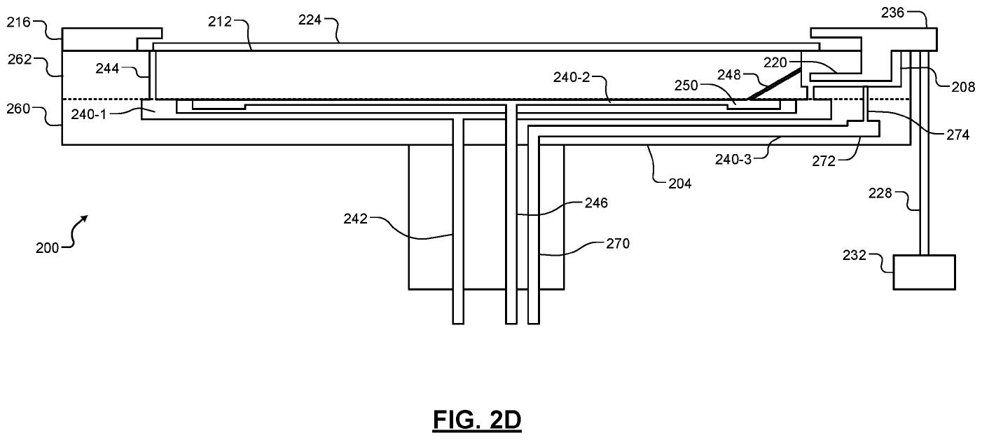

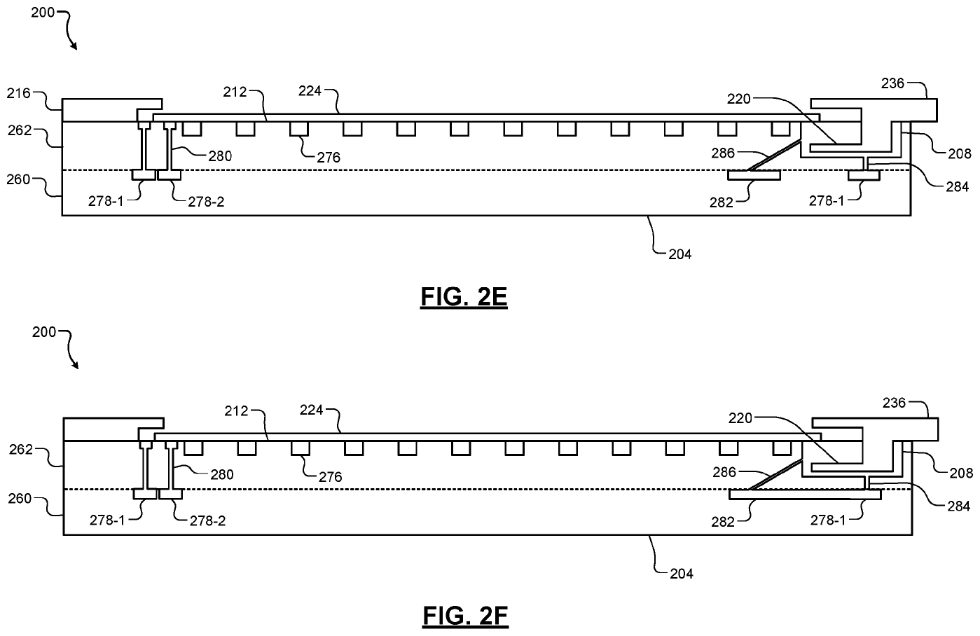

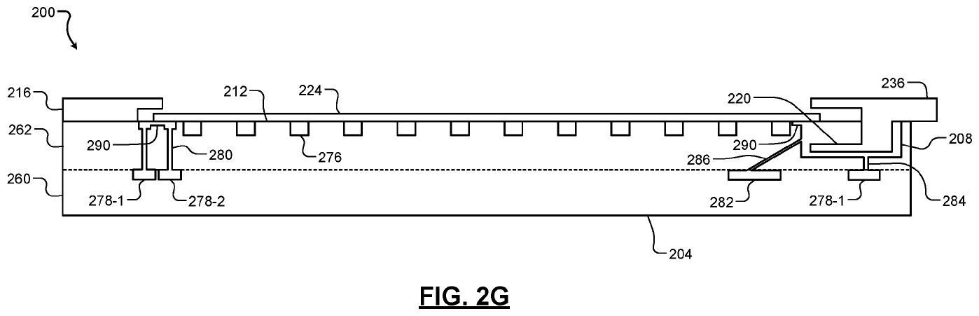

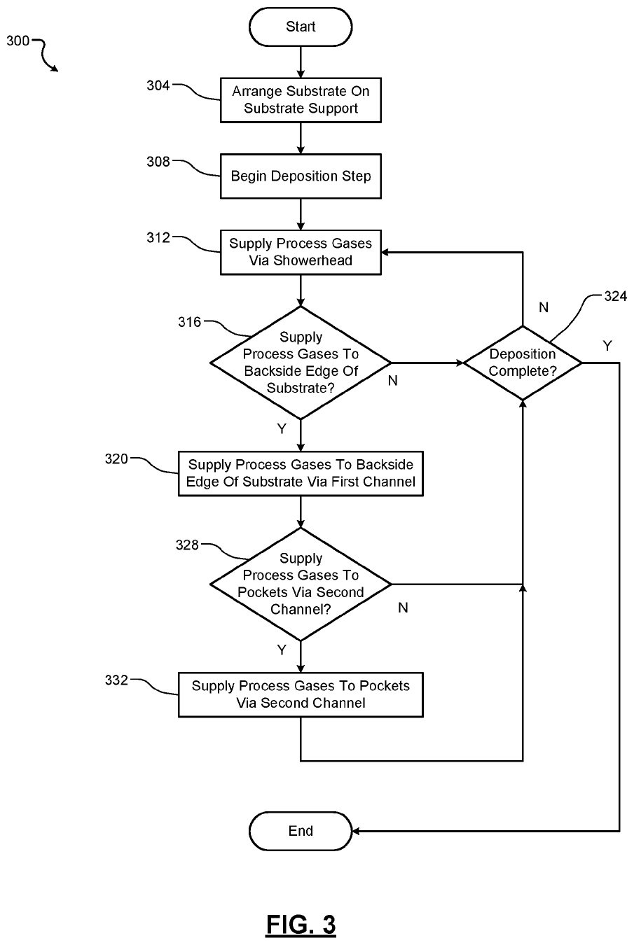

Referring now to FIGS. 2A, 2B, 2C, and 2D, example substrate supports 200 according to the present disclosure are shown in more detail. FIGS. 2A and 2B are cross-sectional views of examples of the substrate supports 200. FIG. 2C is a plan (top down) view of the substrate support 200 of FIG. 2A.

A baseplate 204 of the substrate support 200 comprises one or more recesses or pockets 208. The baseplate 204 may be conductive (e.g., comprised of metal, such as aluminum). In some examples, the baseplate 204 may comprise other materials such as a ceramic material. The pockets 208 are defined in a first (e.g., upper) surface 212 of the substrate support 200/baseplate 204. As shown in FIG. 2C, three of the pockets 208 are distributed uniformly around an outer perimeter of the baseplate 204. As an example, the pockets 208 are spaced circumferentially apart at 120-degree intervals. In some examples, one of the pockets 208 may be offset from an adjacent pocket at an interval greater than or less than the 120-degree interval (e.g., offset by 10 degrees). In other examples, the baseplate 204 comprises fewer or more than three of the pockets 208 distributed uniformly or non-uniformly.

The pockets 208 are configured to receive at least a portion of a carrier ring 216 supported in a lowered position on the substrate support 200. For example, the carrier ring 216 comprises contact fingers 220 extending downward from the carrier ring 216 and radially inward toward a substrate 224 disposed on the substrate support 200. When in the lowered position, the contact fingers 220 are aligned with and disposed within respective ones of the pockets 208. In some examples, an inner edge of the carrier ring 216 overlaps an outer edge of the substrate 224. The carrier ring 216 is not shown in FIG. 2C.

The carrier ring 216 may be raised and lowered using one or more lift pins 228 and respective actuators 232. The actuators 232 may be responsive to a control signal received from a controller (e.g., the controller 160). In one example, an outer edge of the carrier ring 216 extends radially outside of the outer perimeter of the baseplate 204. The lift pins 228 are aligned with the outer edge of the carrier ring 216 outside of the outer perimeter of the baseplate 204. In another example, the carrier ring 216 comprises tabs 236 extending radially outward from the carrier ring 216. The tabs 236 extend outward at locations corresponding to the lift pins 228. In this manner, the lift pins 228 engage the tabs 236 to raise and lower the carrier ring 216. When in the lowered position as shown (e.g., during processing of the substrate 224), the contact fingers 220 are disposed within the pockets 208.

The substrate support 200 according to some examples of the present disclosure comprises two or more plenums or channels 240 configured to supply dedicated flows of different deposition process gases or process gas mixtures to the pockets 208. For example, the substrate support 200 comprises a first channel 240-1 and a second channel 240-2 (referred to collectively as channels 240). The first channel 240-1 supplies a process gas mixture comprising multiple processes gases (e.g., argon and ammonia) to a backside edge of the substrate 224. The second channel 240-2 supplies only one of the process gases (e.g., argon) to the pockets 208. The first and second channels 240-1, 240-2 can also be called first and second gas channels 240-1, 240-2, respectively. In this manner, supply of a process gas mixture and individual process gases in the process gas mixture to different regions of the backside edge of the substrate 224 can be separately controlled.

In an example, a gas mixture comprising multiple process gases (e.g., argon and ammonia) is supplied to the first channel 240-1 through a first inlet channel 242. The first channel 240-1 supplies the gas mixture upward toward a backside edge of the substrate 224 via a first outlet channel 244. For example, the first outlet channel 244 is an annular channel encircling the backside edge of the substrate 224. Conversely, one of the process gases (e.g., argon) is separately supplied to the second channel 240-2 through a second inlet channel 246. The second channel 240-2 supplies the process gas to the pockets 208 via a plurality of second outlet channels 248.

As shown in FIG. 2A, the second channel 240-2 is disposed above the first channel 240-1. The second channel 240-2 supplies an annular plenum 250 located radially inward of the pockets 208. The second outlet channels 248 extend upward and outward (i.e., at an angle) from the annular plenum 250 toward the pockets 208. As shown in FIG. 2B, in another example, the second channel 240-2 is disposed below the first channel 240-1. The second channel 240-2 supplies an annular plenum 252 located below the pockets 208. The second outlet channels 248 extend upward from the annular plenum 252 toward the pockets 208.

The baseplate 204 may comprise a first (e.g., lower) portion 260 and a second (e.g., upper) portion 262. For example, the first portion 260 and the second portion 262 correspond to first and second plates. The first portion 260 and the second portion 262 may be comprised of same or different materials. Using the separate first and second portions 260, 262 to construct the baseplate 204 may facilitate the forming of the channels 240 in the baseplate 204. For example, the channels 240 may be machined into an upper surface of the first portion 260. The first portion 260 and the second portion 262 may then be attached (e.g., brazed, welded, etc.) together to form the baseplate 204. Although shown with only the first portion 260 and the second portion 262, the baseplate 204 may comprise more than two portions attached together. For example, each of the channels 240 may be comprised in a different portion or plate of the baseplate 204. In an example, the first channel 240-1 is defined in the upper surface of the first portion 260 and the second channel 240-2 is defined in a lower surface of the second portion 262.

FIG. 2D shows an example of the substrate support 200 comprising three of the channels 240. In this example, the second channel 240-2 is disposed above the first channel 240-1. The second channel 240-2 supplies the annular plenum 250 located radially inward of the pockets 208. The second outlet channels 248 extend upward and outward from the annular plenum 250 toward the pockets 208. A third channel 240-3 is disposed below the first channel 240-1. A third inlet channel 270 supplies process gases to the third channel 240-3. The third channel 240-3 supplies an annular plenum 272 located below the pockets 208. Third outlet channels 274 extend upward from the annular plenum 272 toward the pockets 208.

In the example shown in FIG. 2D, gas mixtures can be supplied to the backside edge of the substrate 224 and to the pockets 208 through three separate channels. As one example, the first channel 240-1 supplies the process gas mixture comprising multiple process gases (e.g., first and second gases, such as ammonia and argon) to the backside edge of the substrate 224. In other words, the first channel 240-1 supplies the process gas mixture to an entirety of the backside edge (e.g., via the annular outlet channel 244. The process gas mixture may be supplied continuously during a deposition step or process.

The second gas channel 240-2 supplies a subset (e.g., only one) of the process gases of the gas mixture to the pockets 208. In other words, the gas supplied by the second gas channel 240-2 corresponds to one of the gases in the gas mixture supplied by the first gas channel 240-1. In this example, the second gas channel 240-2 supplies the first process gas (e.g., ammonia) to the pockets 208. The second gas channel 240-2 may supply the first process gas to the pockets 208 continuously and/or at periodic intervals.

The third gas channel 240-3 supplies another subset of the process gases of the gas mixture to the pockets 208. The gas supplied by the third gas channel 240-3 may be the same or different from the gas supplied by the second gas channel 240-2. In this example, the third gas channel 240-3 supplies the second process gas (e.g., argon) to the pockets 208. The third gas channel 240-3 may supply the second process gas to the pockets 208 continuously and/or at periodic intervals.

The third gas channel 240-3 may supply the second process gas to the pockets 208 at a same as or different time than the second gas channel supplies the first process gas to the pockets 208. For example, the second gas channel 240-2 supplies the first process gas to the pockets 208 during a deposition step to improve deposition uniformity at an edge of the substrate 224. Conversely, the third gas channel 240-3 supplies the second process gas as a purge gas to purge the pockets 208 subsequent to a deposition step.

Supply (i.e., flow) of the process gases via the channels 240 is controlled using a controller, such as the controller 160, the dose controller 162, etc. The process gases supplied by the channels 240 may be the same as or different from the process gases supplied by the showerhead 140. Accordingly, the controller 160 may be configured to control supply of the process gases to the channels 240 from the same gas delivery system 120. In other examples, the controller 160 may control supply of the process gases to the channels 240 from a different gas delivery system (e.g., different gas sources, valves, etc.).

FIGS. 2E, 2F, and 2G show other example configurations of the substrate support 200. For simplicity, some elements (e.g., inlet channels, the actuator 232 and pins 228, etc.) are not shown. In these and other examples, the substrate support 200 may comprise clamping grooves 276 defined in the upper surface 212 below the substrate 224. A clamping gas is supplied to the clamping grooves 276 to clamp the substrate 224 to the substrate support 200. Typically, a gas pressure within the clamping grooves 276 is less than a pressure within a process volume of the processing chamber (i.e., a chamber pressure above the substrate 224). Accordingly, process gases may leak under a backside of the substrate 224, into the clamping grooves 276, etc.

As shown in FIGS. 2E, 2F, and 2G, the substrate support 200 comprises dedicated purge plenums 278-1 and 278-2 (referred to collectively as purge plenums 278). The purge plenum 278-1 may be disposed radially outside of the outside edge of the substrate to supply a process gas or a purge gas (e.g., argon) to the backside edge of the substrate 224 and to the pockets 208 through respective channels. For example, the purge plenum 278-1 is configured similar to the first channel 240-1 described above.

Conversely, the purge plenum 278-2 is disposed radially inside of the purge plenum 278-1 and the outer edge of the substrate 224 and radially outside of the clamping grooves 276. A purge gas (e.g., argon) is separately supplied to the purge plenum 278-2 and upward through a purge channel 280. The purge gas flows outward from the purge channel 280 toward the backside edge of the substrate 224 and inward toward the clamping grooves 276. In this manner, the purge gas supplied to the purge plenum 278-2 prevents process gas flow under the backside edge of the substrate 224 and into the clamping grooves 276.

A pressure of the purge gases supplied to the purge plenums 278 relative to chamber pressure may be varied. For example, the purge plenum 278-2 may supply the purge gas at a pressure greater than the chamber pressure. In other examples, the purge plenum 278-2 provides the purge gas at a pressure less than the chamber pressure.

As shown in FIGS. 2E and 2G, the substrate support 200 comprises another plenum 282 disposed radially inward of the purge plenum 278-1. The plenum 282 is arranged to supply a dedicated flow of purge and/or process gases to the pockets 208. For example, the plenum 282 is configured similar to the second channel 240-2, second outlet channels 248, and annular plenum 250 described above. Conversely, as shown in FIG. 2F, the purge plenum 278-1 supplies gases to the pockets 208 via both outlet channels 284 and 286.

As shown in FIG. 2G, the upper surface 212 of the substrate support 200 comprises an annular recess or channel 290 between the purge plenum 278-1 and the purge plenum 278-2. The channel 290 allows fluid communication between the purge plenum 278-1 and the purge plenum 278-2 at the upper surface 212. Accordingly, flow of the purge gas outward from the purge channel 280 toward the backside edge of the substrate 224 is increased, which reduces the likelihood of liftoff of the substrate 224 from the substrate support 200. Further, supply of purge gas from the purge plenum 278-2 to the pockets 208 is increased. A depth of the channel 290 may be varied to control the desired amount of purge gas flow.

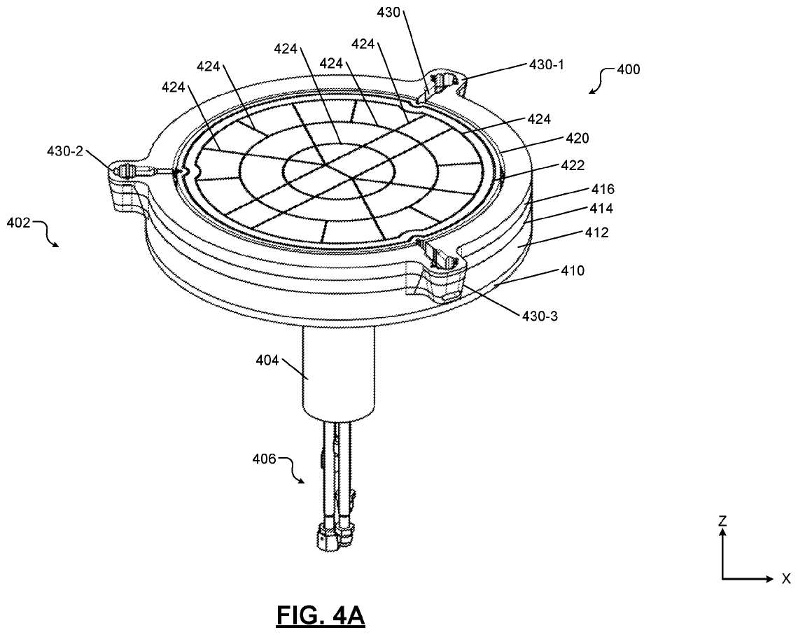

FIG. 3 shows an example method 300 of supplying gas mixtures to a backside edge of a substrate arranged on a substrate support according to the present disclosure. For example, the method 300 may be performed by the controller 160, the gas delivery system 120, etc. At 304, a substrate is arranged on a substrate support for processing (e.g., a deposition step). For example, a substrate is transferred to a carrier ring in a raised position and the carrier ring is lowered to lower the substrate onto the substrate support.

At 308, processing (e.g., a deposition step) begins. At 312, a deposition process gas mixture is supplied to a processing chamber via a gas distribution device (e.g., a showerhead). At 316, the method 300 determines whether to supply process gases to a backside edge of the substrate. For example, process gases may be supplied to the backside edge continuously during the deposition step or only during certain intervals. In one example, the process gases are supplied to the backside edge in pulses, in intermittent periods during the deposition step, conditionally (e.g., in response to process parameters meeting certain criteria), etc. If true, the method 300 continues to 320. If false, the method 300 continues to 324.

At 324, the method 300 determines whether the deposition step is complete. If true, the method 300 ends. If false, the method 300 continues to 312.

At 320, process gases are supplied to the backside edge of the substrate via a first channel (e.g., the first channel 240-1). At 328, the method 300 determines whether to supply process gases to the pockets via a second channel (e.g., the second channel 240-2). For example, process gases may be supplied to the pockets 208 via the second channel 240-2 continuously during the deposition step or only during certain intervals. If true, the method 300 continues to 332. If false, the method 300 continues to 324.

At 332, one or more process gases are supplied to the backside edge of the substrate via the second channel 240-2. In one example, one of the process gases supplied via the first channel 240-1 is supplied to the pockets 208 via the second channel 240-2. In another example, one of the process gases supplied via the first channel 240-1 is supplied to the pockets 208 via the second channel 240-2 and another one of the process gases supplied via the first channel 240-1 is supplied to the pockets 208 via a third channel (e.g., the third channel 240-3).

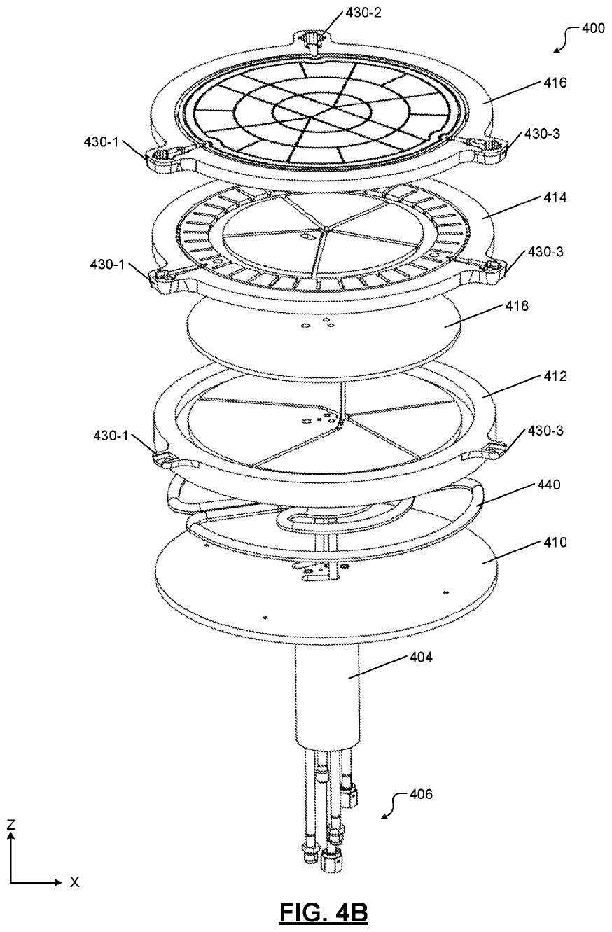

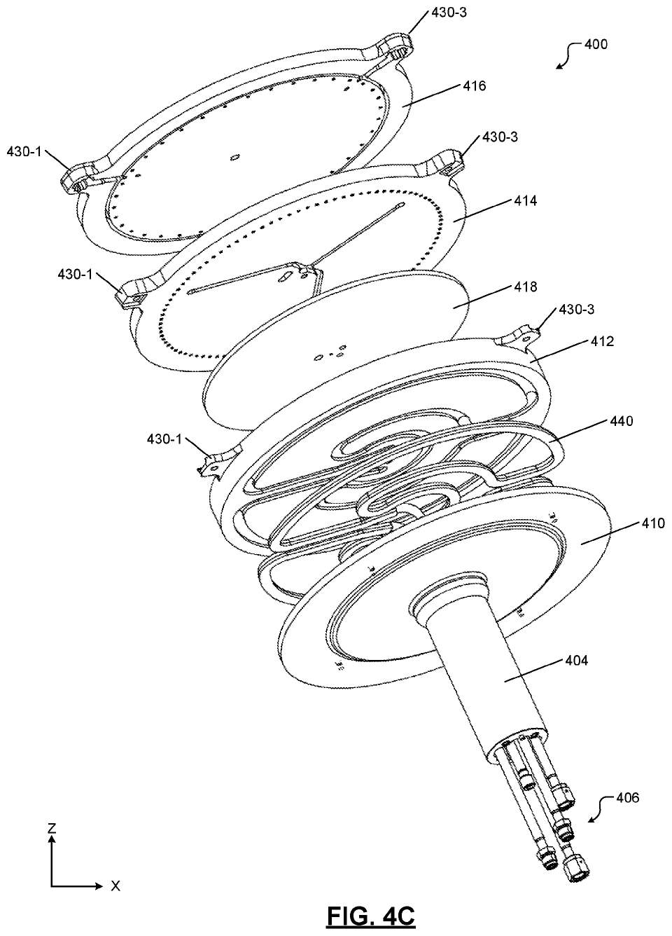

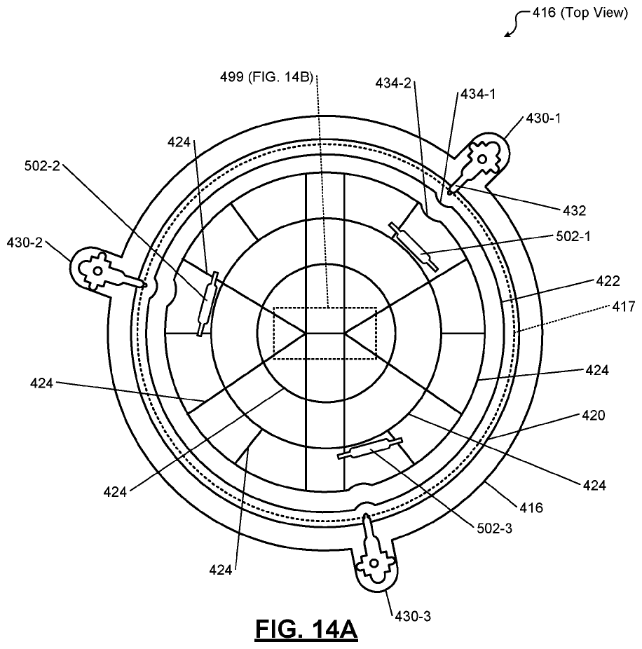

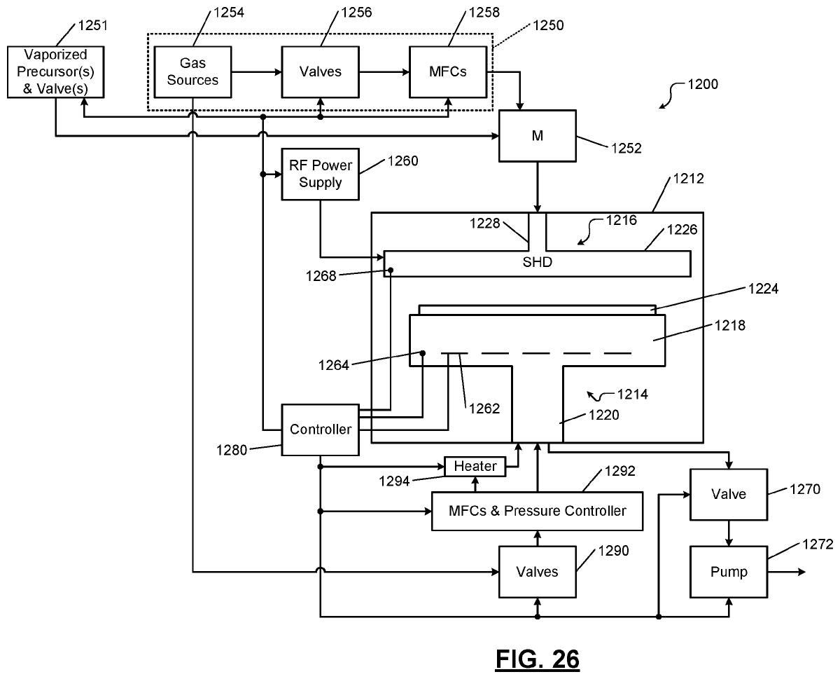

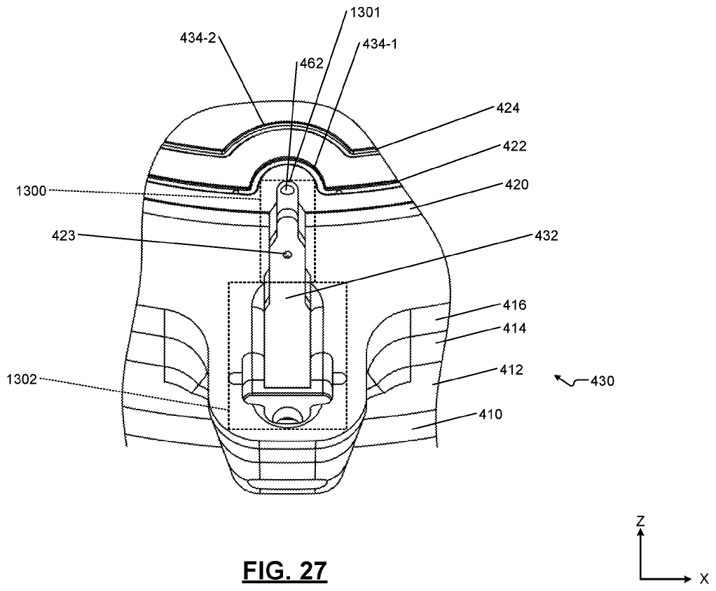

Additional examples of pedestal designs are shown and described below with reference to FIGS. 4A-25B. For example, a pedestal comprising multiple disjoint plenums is shown and described with reference to FIGS. 4A-12. In addition to the disjoint plenums, the pedestal comprises many features that provide various advantages, which are initially summarized below and subsequently described in detail. Additional examples of pedestal designs comprising various combinations of these plenums and features are shown and described with reference to FIGS. 13-25B. An example of a substrate processing system that can utilize any of the pedestal designs described herein is shown and described with reference to FIG. 26. The remaining figures show arrangements of conduits that supply gases to the plenums in further detail.

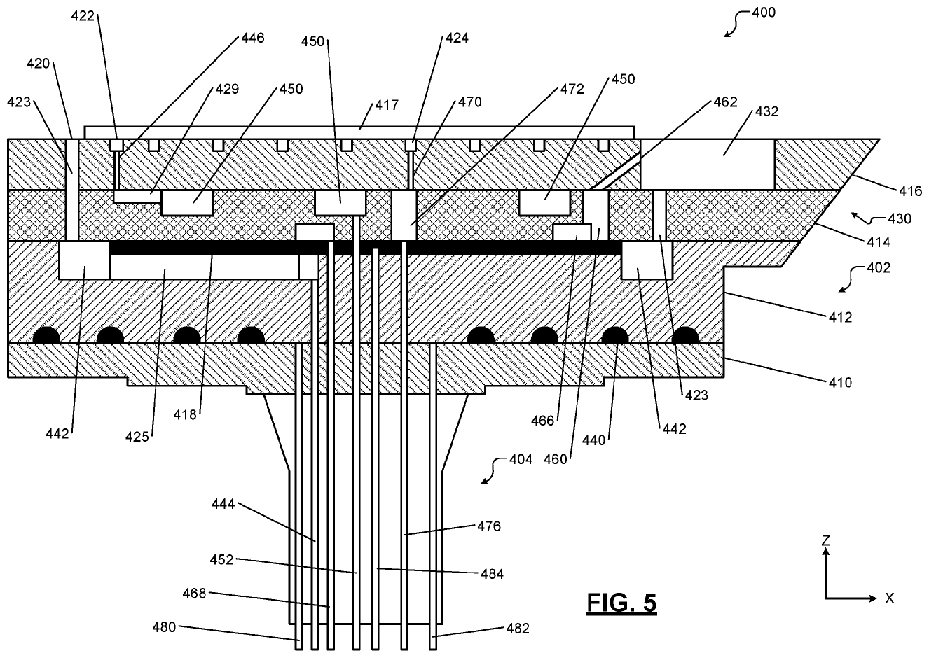

Some of the pedestal designs described below are similar to those described above with reference to FIGS. 1-3 and are shown and described below in further detail. For example, the pedestal designs shown in FIGS. 2E and 2F are shown in further detail in FIGS. 5 and 13, respectively. Any single or combination of features shown and described with reference to FIGS. 1-3 can be implemented in the examples shown and described with reference to FIGS. 4-25. The pedestals described herein are also generally called substrate supports.

Briefly, the features of the pedestals described below provide the following advantages. In some applications, processed substrates show evidence of deposition on the backside (i.e., the underside of the substrates) that rests on the top surface of the pedestal. In particular, the backside exhibits deposition in areas where the top surface of the pedestal comprises grooves (e.g., vacuum clamping grooves) and comprises pockets that support a carrier ring carrying a substrate during substrate transfer. One way to alleviate the problem of backside deposition is to supply an edge gas through a groove on the top surface of the pedestal such that the edge gas flows radially outwards from under the substrate. The radially outward gas flow prevents diffusion of process gases into areas under the substrate, which in the turn prevents backside deposition and also minimizes corrosion caused by process chemistries in radially inner portions of the top surface of the pedestal.

Further, various components of the pedestals can cause cold spots and temperature nonuniformity on the substrates. For example, the pocket areas can cause cold spots on portions of the substrate that lie above the pocket areas. To avoid the cold spots, the pocket area can be reduced in size (e.g., the pockets can be recessed radially outwards). In addition, a gas can be supplied through a separate plenum into the pockets to improve process uniformity on the substrates at locations of the substrates that lie above the pocket areas.

Further, the gas supplied through the separate plenum into the pockets can be heated to locally increase the temperature of the substrates in the regions directly above the pockets, which improves temperature nonuniformity and reduces cold spots on the substrates in the regions directly above the pockets. For example, the temperature of the gas (e.g., power supplied to a heater used to heat the gas) can be selected based on wafer thickness measured during substrate processing. Further, an inner diameter of the groove on the top surface of the pedestal that supplies the edge gas can be increased to minimize substrate overhang above the groove, which improves nonuniformity at substrate edges.

Furthermore, ceramic springs are typically used on the top surface of the pedestal to support the substrate before clamping. The ceramic springs can also cause cold spots on portions of the substrate that lie above the ceramic springs. In some examples, the ceramic springs can be removed to eliminate the cold spots caused by the ceramic springs. Other causes of cold spots include circular cutouts near the center of the top surface of the pedestal in which holes are provided for vacuum clamping. The pedestals described below eliminate these cutouts. Instead, the clamping grooves in these pedestals have a narrow width and increased depth to accommodate multiple holes for vacuum clamping in the clamping grooves without using the cutouts. The narrow width of the clamping grooves minimizes the cold spots caused by the clamping grooves on the substrates.

In some examples, the clamping grooves are rounded to reduce adverse effects of material that builds up along the edges of the clamping grooves due to reaction of the top surface of the pedestal with process chemistries. For example, the buildup along the edges of the clamping grooves tends grow and raise the substrate, which adversely affects substrate clamping and causes nonuniformity issues. Due to the rounding of the clamping grooves, even if material builds up along the edges of the clamping grooves, a gap exists between the substrate and the buildup, which prevents the buildup from interfering with substrate clamping, which in turn prevents process gases from leaking into areas underneath the substrate and compromising substrate clamping. Thus, the rounded grooves help in preventing process variations due to surface irregularities caused by material build on the top surface of the pedestal.

In addition, heaters embedded in the pedestals typically tend to be sparse (i.e., include a coil with only two or three turns that are not distributed uniformly across the radius of the pedestals), which causes temperature nonuniformity in substrates. Instead, the pedestals described below comprise a dense heater (i.e., includes a coil with more than three turns). The heater coil is also distributed radially uniformly across the pedestals, which improves radial temperature uniformity in the substrates.

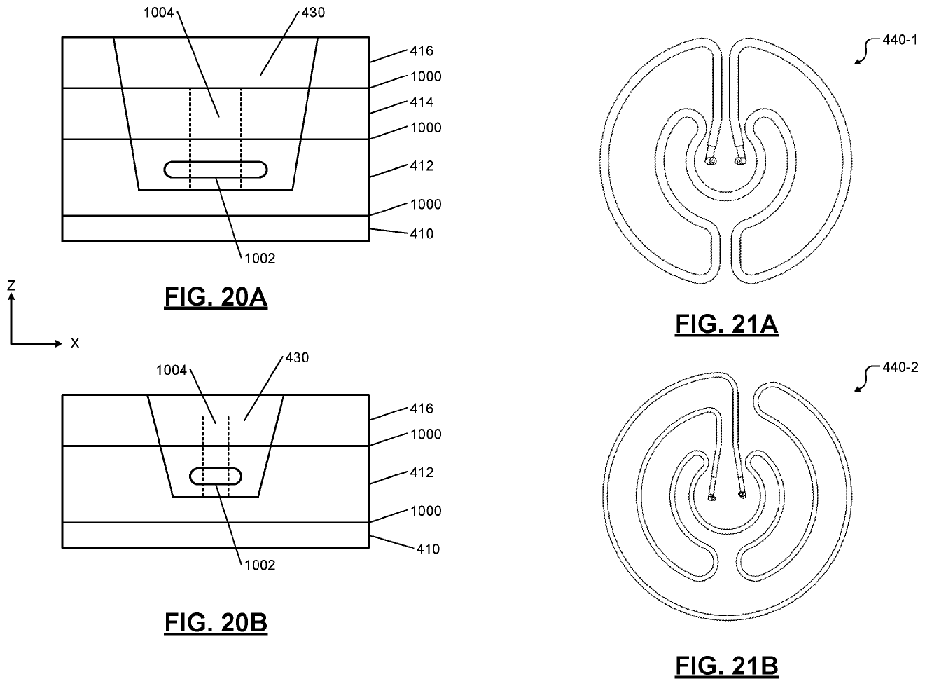

Also, the pedestals are typically formed by brazing multiple plates together. The pockets comprise a slot in which a nut plate and a washer are arranged to secure a wheel block assembly in the pockets (see FIGS. 20A and 20B). The wheel block assembly receives and supports a carrier ring and substrate holder assembly used to transport substrates between stations. (see FIGS. 20A and 20B). If the slot is formed at an interface at which two plates are brazed (i.e., in the middle of the brazing plane), the bonding strength of the brazing between the two plates is reduced since the area of contact between the two plates is reduced by the slot. Further, the washer tends to expand due corrosion and heat, which delaminates the pockets.

Instead, in the pedestals described below, the slot in the pockets is formed and located away from the brazing interfaces of the plates such that the slot is not at an interface at which two plates are brazed (i.e., the slot is not in the middle of the brazing plane). Accordingly, a larger surface area of the plates is available for brazing the plates, which results in increased bonding strength between the plates. Further, when the washer expands, the mechanical force from the expansion is less than the bonding force keeping the plates together, which prevents delamination of the pocket. These and other features of the pedestals of the present disclosure are described below in detail.

Throughout the following description of the pedestals shown in FIGS. 4A-25B, an axis parallel to a plane in which the plates of the pedestals lie is called a horizontal axis or x-axis shown in FIGS. 4A-22B; and an axis perpendicular to the plane in which the plates of the pedestals lie is called a vertical axis, the axis of the pedestals, or z-axis shown in FIGS. 4A-22B.

FIGS. 4A-12 show a pedestal 400 comprising multiple disjoint plenums and other features. FIG. 4A shows a perspective view of the pedestal 400. FIGS. 4B and 4C show exploded views of the pedestal 400 shown in FIG. 4A. Various features of the pedestal 400 are visible in FIGS. 4A-4C. These features are described initially briefly with reference to FIGS. 4A-4C and are subsequently described in detail with reference to FIGS. 5-12.

In FIGS. 4A-4C, the pedestal 400 is made of a metallic material (e.g., aluminum or an alloy). In some examples, the pedestal 400 can be made of other materials such as a ceramic material. The pedestal 400 comprises a base portion 402 and a stem portion 404. The base portion 402 is generally cylindrical and extends radially along the x-axis. The stem portion 404 is also generally cylindrical and has a smaller diameter than the base portion 402. The stem portion 404 is coupled to a bottom of the stem portion 404 near the center of the base portion 402. The stem portion 404 extends along the z-axis. The stem portion 404 is hollow and confines multiple conduits as described below.

The walls of the stem portion 404 are thick enough to provide sufficiently high creep resistance at high process temperatures. A creep resistance of a material is the ability of the material to resist creep, which is a tendency of the material to slowly deform over a long period of exposure to high levels of stress. Creep deformation generally occurs when a material is stressed at a temperature near its melting point. The creep resistance can be generally defined in terms of the amount of creep produced by an amount of strain placed on the material for an amount of time. Stated differently, the creep resistance is defined by the stress level required to produce a nominal strain (e.g., 0.1, 0.2, or 0.5%) in a time period (e.g., 100,000 hours). The creep resistance is affected by factors such as properties of the material, length of time for which the material is exposed to a stressor, temperature at which the material is exposed to the stressor, and power of the stressor (e.g., thermal load imposed on the stem portion 404 during substrate processing). Accordingly, the material and thickness of the material for the stem portion 404 are selected to provide sufficiently high creep resistance at high process temperatures. In some examples, thin walls can be used, which can reduce heat loss and power consumed by the pedestal to maintain a setpoint temperature.

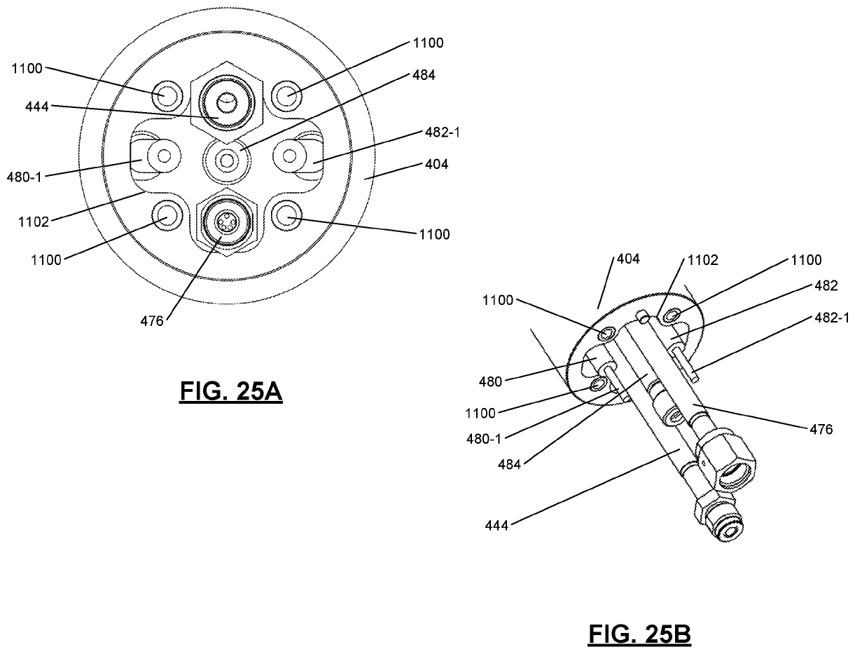

A plurality of gas conduits generally shown at 406 are disposed through the stem portion 404 and are connected to various plenums formed in the base portion 402 by different plates of the base portion 402 as described below. The conduits 406 supply gases to the plenums as described below. Additionally, as described below, additional conduits for supplying power to a heater disposed in the base portion 402 and for sensing a temperature of the base portion 402 are also disposed through the stem portion 404. The conduits 406 are shown in detail in FIGS. 23A-25B.

As shown in the exploded views of the pedestal 400 in FIGS. 4B and 4C, the base portion 402 comprises four plates that are joined (e.g., brazed) together: a first plate 410, a second plate 412, a third plate 414, and a fourth plate 416. The plates 410, 412, 414, 416 are generally cylindrical. The stem portion 404 is coupled to the first plate 410. A heater coil 440 is disposed in the second plate 412. The various plenums described below are defined by the second, third, and fourth plates 412, 414, 416. In some examples, a fifth plate 418 (see FIG. 5) is disposed between the second and third plates 412, 414 to further define these plenums as described below in detail. The fourth plate 416 is also called the top plate 416 of the pedestal 400 on which a substrate 417 (see FIG. 5) is placed during processing. Various features of the plates 410-418 are visible in FIGS. 4A-4C. These features are described initially briefly with reference to FIGS. 4A-4C and are subsequently described in detail with reference to FIGS. 5-12.

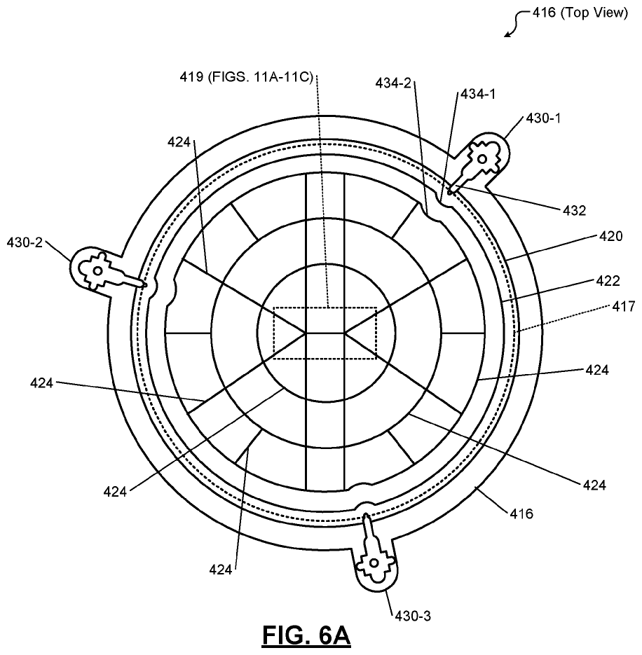

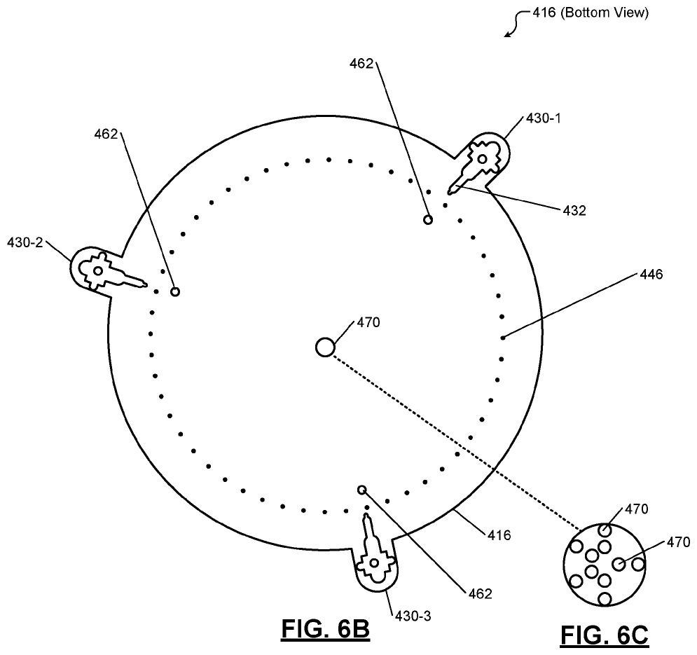

Referring to FIG. 4A, the top plate 416 comprises various grooves. For example, the top plate 416 comprises an edge gas groove 420, a purge gas groove 422, and a plurality of vacuum clamping grooves generally shown at 424. The vacuum clamping grooves 424 are hereinafter simply called the clamping grooves 424. The clamping grooves 424 comprise all of the grooves shown within (i.e., radially inside) the purge gas groove 422. Some of the clamping grooves 424 are concentric (i.e., annular or circular) while some of the clamping grooves 424 extend radially. The concentric and radial clamping grooves are generally referred to as clamping grooves 424 and also individually referred to as concentric clamping grooves 424 and radial clamping grooves 424. Some of the radial clamping grooves 424 intersect the concentric clamping grooves while some of the radial clamping grooves interconnect the concentric clamping grooves. The radial clamping grooves that intersect the concentric clamping grooves are longer than the radial clamping grooves that interconnect the concentric clamping grooves. Thus, all of the radial and concentric (i.e., annular or circular) clamping grooves 424 are interconnected. The clamping grooves 424 are shown in detail in FIGS. 6A-6C.

As seen in FIG. 6A, the edge gas groove 420 and the purge gas groove 422 are concentric (i.e., annular or circular). The edge gas groove 420 is radially the outermost groove on the top surface of the fourth plate 416. An inner diameter (ID) of the edge gas groove 420 is greater than a diameter of the substrate 417 (represented by the dotted circle). An outer diameter (OD) of the edge gas groove 420 is less than a diameter of the fourth plate 416. An OD of the purge gas groove 422 is less than the ID of the edge gas groove 420 and is also less than the diameter of the substrate 417.

In general, the purge gas groove 422 has a smaller diameter than the edge gas groove 420 and the substrate 417. The purge gas groove 422 radially circumscribes the clamping grooves 424. The ID of the purge gas groove 422 is greater diameter than an OD of the outermost circular clamping groove 424. In general, the diameter of the purge gas groove 422 is greater than the diameter of the outermost circular clamping groove 424. The grooves 420, 422, 424 are connected to respective disjoint plenums in the base portion 402 of the pedestal 400 via one or more gas channels as described below with reference to FIG. 5 onwards.

In FIG. 4A, the pedestal 400 comprises a plurality of pockets 430-1, 430-2, and 430-3 (individually called the pocket 430 and collectively called the pockets 430). The pockets 430 support a carrier ring (not shown) when the substrate 417 is transported to and from the pedestal 400 as described below with reference to FIG. 26. The pockets 430 are formed along an outer diameter (OD) (e.g., along an outer upper edge or periphery) of the base portion 402 of the pedestal 400. A plurality of the plates 412-416 form portions of the pockets 430 as seen in FIGS. 4B and 4C. The pockets 430 are formed when the plurality of plates 412-416 are bonded (e.g., brazed, welding, soldering, etc.) together. Thus, the pockets 430 are homogeneous with (i.e., integral parts of) the plurality of plates 412-416 and the base portion 402 of the pedestal 400. The pockets 430 are formed about 120 degrees apart from each other. The pockets 430 protrude out of the OD of the of the base portion 402 of the pedestal 400 and extend along the x and y axes (see FIGS. 21A and 21B). The top ends of the pockets 430 are flush or level with (i.e., lie in the same plane as) the top surface of the fourth plate 416.

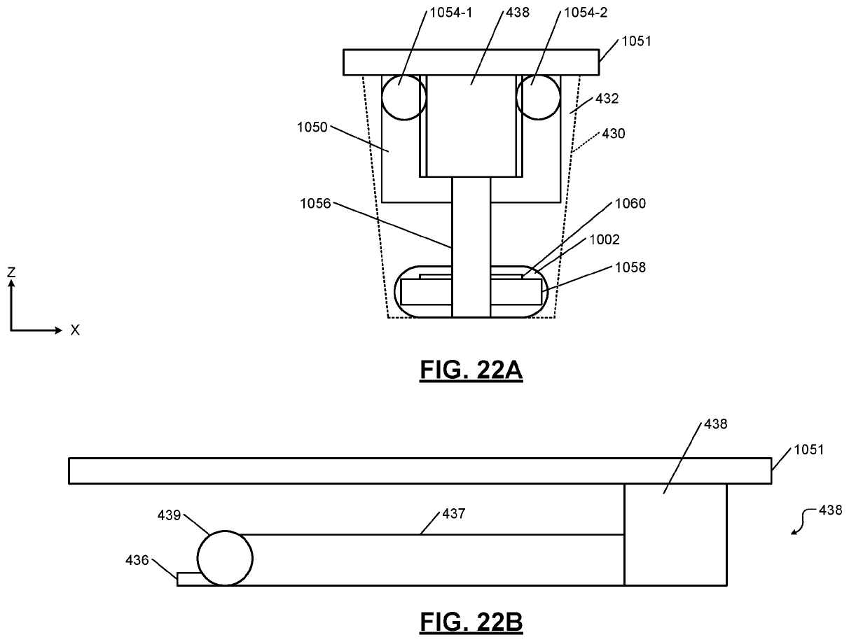

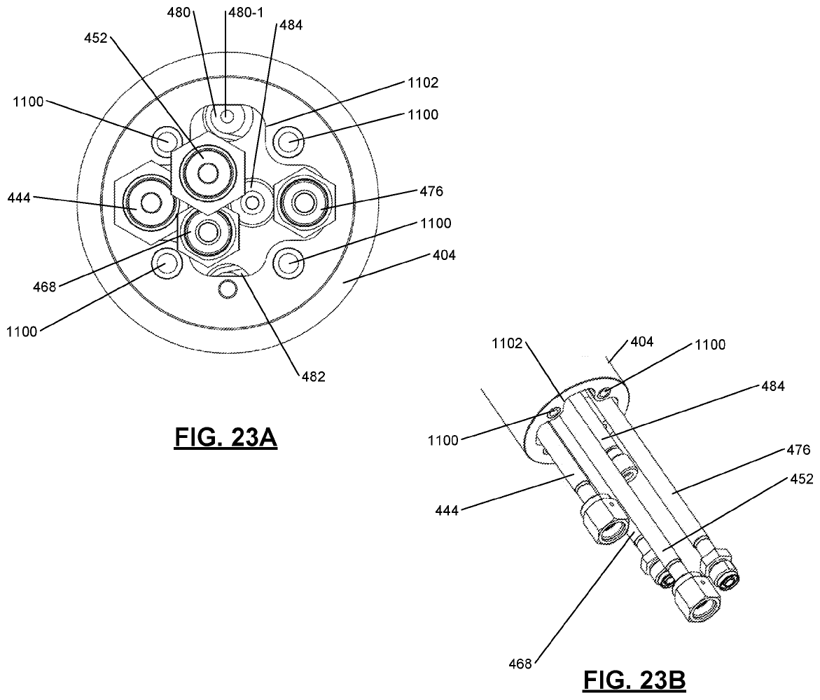

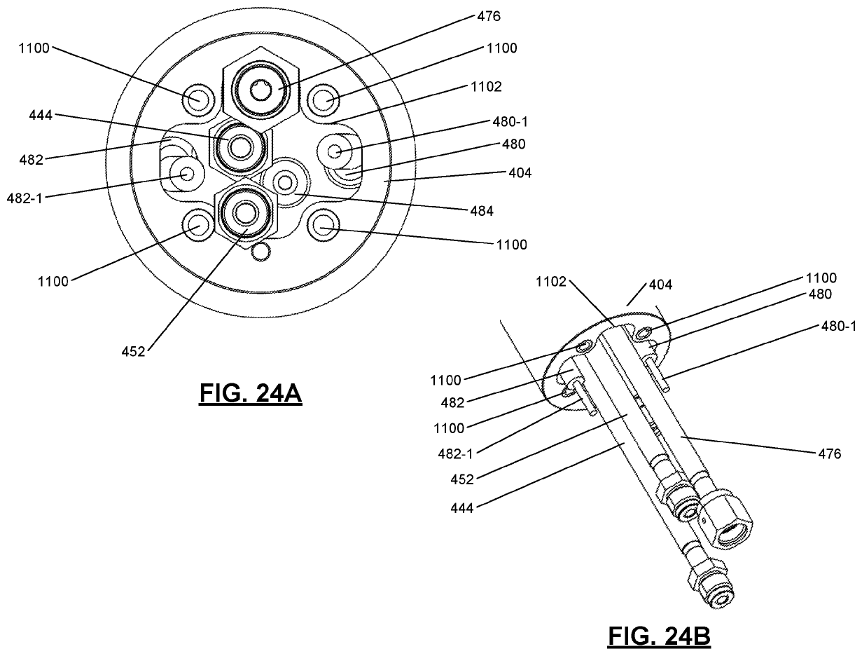

Each of the pockets 430 comprises a slot 432 that extends radially into an outer periphery of the base portion 402 of the pedestal 400. The edge gas groove 420 intersects slots 432 in the pockets 430. At least one of the through holes 423 in the edge gas groove 420 lies in each of the slots 432 (see FIG. 9). As shown and described below with reference to FIGS. 22A and 22B, a carrier ring and substrate holder assembly 438 with a protrusion 436 to support a substrate 417 (see FIG. 5) is disposed in the slot 432 in the pocket 430.

In some examples, the pedestal 400 comprises an additional set of holes (see FIG. 5) that open into the pockets 430 and that is supplied with an edge gas by a separate plenum in the base portion 402 of the pedestal 400 as described below. The pedestal 400 comprises a fifth plate (see FIG. 5) that separates some of the plenums as described below. These and various other features of the plates 412-416 visible in the exploded views shown in FIGS. 4B and 4C are described below in detail with reference to FIGS. 5-12.

FIG. 5 shows an example of a cross-sectional view of the pedestal 400. A first end of the stem portion 404 connected to the first plate 410 is flared (i.e., extends radially outwardly) proximate to the first plate 410. For example, the stem portion 404 has a Y-shaped profile at the first end that attaches to the first plate 410. The heater coil 440 includes an inner loop located within a circular region at the center of the base portion 402, where the circumference of the circle passes through the two prongs of the Y-shaped profile of the stem portion 404. The wall of the stem portion 404 is also made thick to improve creep resistance at high process temperatures. The Y-shaped profile and increased thickness of the stem portion 404 improve thermal conduction between the base portion 402 and the stem portion 404.

The heater coil 440 comprising a plurality of turns (e.g., more than three turns) is disposed in a slot on a bottom surface of the second plate 412. The heater coil 440 is disposed (e.g., sandwiched) between the bottom surface of the second plate 412 and a top surface of the first plate 410. The turns of the heater coil 440 are distributed radially from the center of the second plate 412 to an OD of the second plate 412. In some examples, the turns of the heater coil 440 are distributed uniformly. Thus, the turns of the heater coil 440 are distributed radially uniformly from the center of the base portion 402 of the pedestal 400 to the OD of the base portion 402 of the pedestal 400. For example, a radial gap between adjacent turns of the heater coil 440 may be uniform. Thus, radial sections or zones of the base portion 402 can be heated uniformly to minimize temperature gradient and improve temperature uniformity radially across the base portion 402. An example of the heater coil 440 with more than three turns (e.g., four turns) is shown in FIG. 21B.

While the heater coil 440 with more than three turns are shown as an example, in some examples, the pedestal 400 can also comprise the heater coil 440 with three or fewer number of turns, and the fourth and any additional turns can be optional. An example of the heater coil 440 with three turns is shown in FIG. 13, which shows that a heater coil with additional (i.e., more than three) turns is optional as indicated by showing a fourth coil using dotted lines in FIG. 13. An example of the heater coil 440 with three turns is shown in FIG. 21A.

The second plate 412 comprises a circular slot in a top surface of the second plate 412. In some examples, a fifth plate 418 is integrated with the second plate 412 or the third plate 414. In some embodiments, the fifth plate 418 is arranged between 412 and 414 as a separate plate. For example, the fifth plate 418 can be inserted into the circular slot in the second plate 412. A bottom surface of the fifth plate 418 is brazed to a top surface of the second plate 412 in the circular slot in the second plate 412. A top surface of the fifth plate 418 is brazed to a bottom surface of the third plate 414. The top surface of the fifth plate 418 is flush with (i.e., in level with or in the same plane as) the top surface of the second plate 412 and the bottom surface of the third plate 414. A diameter of the circular slot and the fifth plate 418 is less than a diameter of the edge gas groove 420 and a diameter of the substrate 417. The fifth plate 418 keeps an edge gas plenum and a pocket edge gas plenum (described below) disjoint (i.e., separate and independent from each other) as explained below in detail.

Throughout the present disclosure, the arrangements of various plates and plenums in the base portion 402 are described in detail. However, these arrangements are non-limiting examples. For example, the plates and the plenums may be stacked differently than described. For example, one or more plates of the base portion 402 could be fused/integrated. For example, locations of one or more plenums within the base portion 402 can be different than those shown and described.

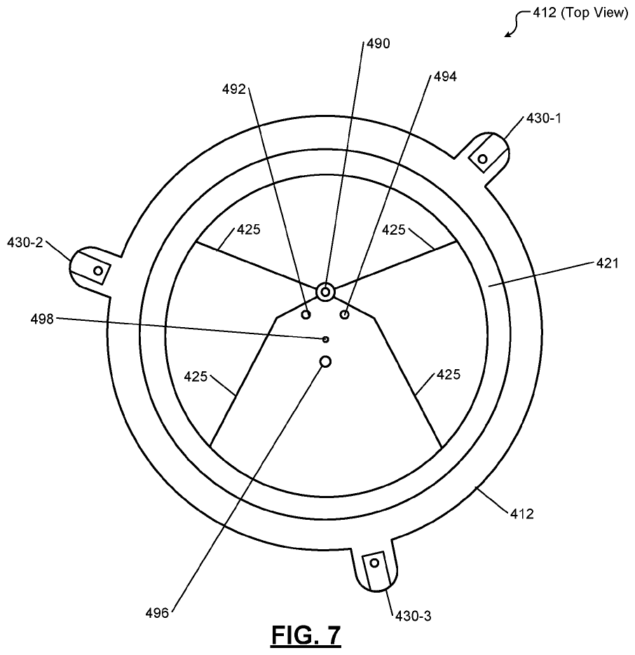

The top surface of the second plate 412, the bottom surface of the fifth plate 418, and through holes 423 in the third and fourth plates 414, 416 define an edge gas plenum 442. The edge gas groove 420, the through holes 423 in the third and fourth plates 414, 416, and the edge gas plenum 442 can be collectively called the edge gas plenum 442. The diameter of the pitch circle of the through holes 423 and the edge gas groove 420 lie inside the edge gas plenum 442. The through holes 423 open in the edge gas groove 420 on the top surface of the fourth plate 416. A conduit 444 passes through the first plate 410 and partially through the second plate 412 and is connected to the edge gas plenum 442. The edge gas groove 420, the through holes 423, the edge gas plenum 442, and the conduit 444 are in fluid communication with each other. The edge gas plenum 442 is shown and described below in further detail with reference to FIG. 7. The edge gas groove 420, the through holes 423, the edge gas plenum 442, and the conduit 444 may be called the first groove 420, the first set of holes, the first plenum 442, and the first conduit 444, respectively.

A top surface of the third plate 414, a bottom surface of the fourth plate 416, and through holes 446 define a purge gas plenum 450. The purge gas groove 422, the through holes 446, and the purge gas plenum 450 can be collectively called the purge gas plenum 450. The through holes 446 open in the purge gas groove 422 on the top surface of the fourth plate 416. A conduit 452 passes through the first, second, and fifth plates 410, 412, 418 and partially through the third plate 414 and is connected to the purge gas plenum 450. The purge gas groove 422, the through holes 446, the purge gas plenum 450, and the conduit 452 are in fluid communication with each other.

The purge gas groove 422, the through holes 446, the purge gas plenum 450, and the conduit 452 are disjoint from (i.e., are not in fluid communication with) the edge gas groove 420, the through holes 423, the edge gas plenum 442, and the conduit 444. The purge gas plenum 450 is shown and described below in further detail with reference to FIG. 9. The purge gas groove 422, the through holes 446, the purge gas plenum 450, and the conduit 452 may be called the second groove 422, the second set of holes, the second plenum 450, and the second conduit 452, respectively.

The bottom surface of the third plate 414, through holes 460 in the third plate 414, and angular holes 462 in the fourth plate 416 define a pocket edge gas plenum 466. In some examples, the angular holes 462 are drilled through the fourth plate 416 and extend angularly upwards and radially outwards through the fourth plate 416 at an acute angle relative to the z-axis and open into the pockets 430. In some examples, a gas conduit that connects the plenum to the angular holes 462 may extend vertically upward from the plenum and radially outward to connect to the angular hole 462. In some examples, one or more pockets 430 of the pedestal 400 may each have one or more angular holes 462. In some examples, not all pockets may have an angular hole 462. The through holes 460, the angular holes 462, and the pocket edge gas plenum 466 can be collectively called the pocket edge gas plenum 466. A conduit 468 passes through the first, second, and fifth plates 410, 412, 418 and is connected to the pocket edge gas plenum 466. The angular holes 462, the through holes 460, the pocket edge gas plenum 466, and the conduit 468 are in fluid communication with each other.

The angular holes 462, the through holes 460, the pocket edge gas plenum 466, and the conduit 468 are disjoint from (i.e., are not in fluid communication with) the through holes 423, the edge gas plenum 442, and the conduit 444. The angular holes 462, the through holes 460, the pocket edge gas plenum 466, and the conduit 468 are also disjoint from (i.e., are not in fluid communication with) the through holes 446, the purge gas plenum 450, and the conduit 452. The pocket edge gas plenum 466 is shown and described below in further detail with reference to FIG. 9. The pocket edge gas plenum 466, the angular holes 462, and the conduit 468 may be called the third plenum 466, the third set of holes, and the third conduit 468, respectively.

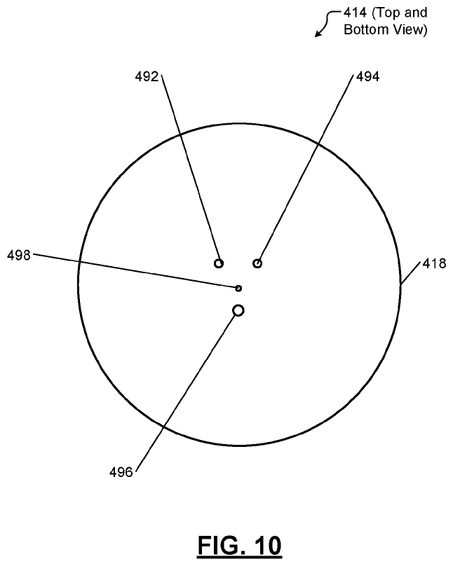

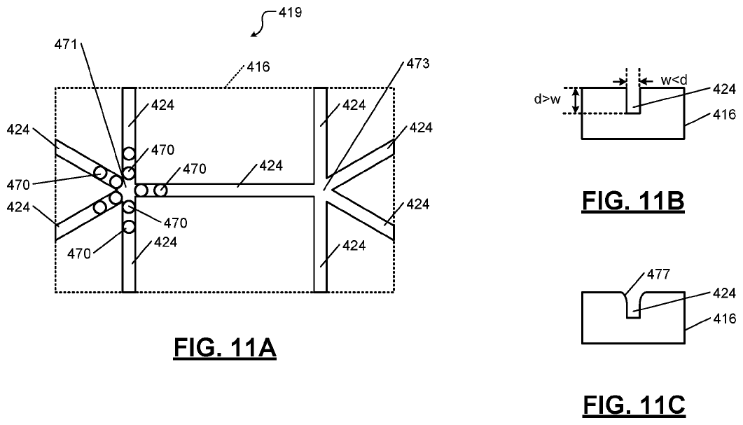

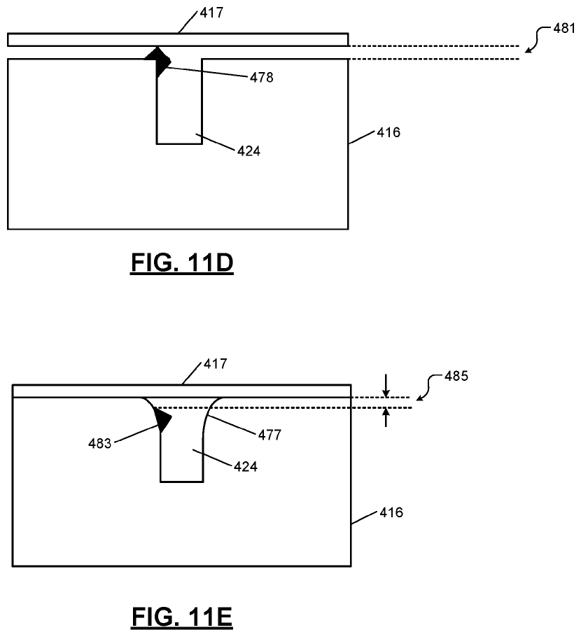

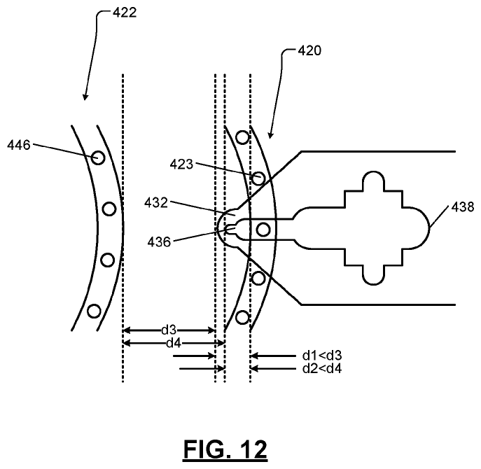

The clamping grooves 424 on the top surface of the fourth plate 416, through holes 470 in the fourth plate 416 (shown in FIGS. 6A-6C), and a through hole 472 in the third plate 414 define a vacuum clamping plenum. The clamping grooves 424, the through holes 470, the through hole 472, the clamping grooves 424 are collectively called the vacuum clamping plenum generally identified at 472. A conduit 476 passes through the first, second, and fifth plates 410, 412, 418 and is connected to the through hole 472. The through holes 470, the through hole 472, the clamping grooves 424, and the conduit 476 are in fluid communication with each other. Thus, the conduit 476 is connected to the vacuum clamping plenum 472. The vacuum clamping plenum 472 is shown and described below in further detail with reference to FIGS. 6A-6C and 11A-11E. The vacuum clamping plenum 472 and the conduit 476 may be called the fourth plenum 472 and the fourth conduit 476, respectively.

The through holes 470, the through hole 472, the clamping grooves 424, and the conduit 476 are disjoint from (i.e., are not in fluid communication with) the angular holes 462, the through holes 460, the pocket edge gas plenum 466, and the conduit 468. The through holes 470, the through hole 472, the clamping grooves 424, and the conduit 476 are also disjoint from (i.e., are not in fluid communication with) the edge gas groove 420, the through holes 423, the edge gas plenum 442, and the conduit 444. The through holes 470, the through hole 472, the clamping grooves 424, and the conduit 476 are also disjoint from (i.e., are not in fluid communication with) purge gas groove 422, the through holes 446, the purge gas plenum 450, and the conduit 452.

Additionally, a pair of conduits 480, 482 pass through the stem portion 404 of the pedestal 400 and through the first plate 410 and is connected to the heater coil 440. Power is supplied to the heater coil 440 through the conduits 480, 482 as described below with reference to FIG. 26. A conduit 484 passes through the stem portion 404 of the pedestal 400 and through the first and second plates 410, 412 and partially through the fifth plate 418 and is connected to the fifth plate 418. The conduit 484 comprises a temperature sensor (not shown) at the end of the conduit 484 that is connected to the fifth plate 418 to sense the temperature of the pedestal 400 (e.g., temperature of the base portion 402 of the pedestal 400). In some examples, the conduit 484 may pass through the fifth plate 418 and may contact the bottom surface of the third plate 414 or may be inserted into the bottom of the third plate 414. The conduits 406 collectively shown in FIG. 1 comprise the conduits 444, 452, 468, 476, 480, 482, and 484.

The supply of various gases to the various plenums during substrate processing is shown and described below with reference to FIG. 26. Briefly, a first gas (e.g., an inert gas or a mixture of an inert gas and hydrogen gas), which is also called an edge gas, is supplied through the first plenum (i.e., the edge gas plenum) 442. The edge gas improves edge uniformity along the edge (e.g., OD and bevel edges) of the substrate 417 during substrate processing.

A second gas (e.g., an inert gas), which is also called a purge gas, is supplied through the second plenum (i.e., the purge gas plenum) 450. The second gas flows radially outwards from under the substrate 417, which prevents deposition on the backside of the substrate 417 (i.e., the side of the substrate 417 that lies on the top surface of the fourth plate 416). The second gas also prevents process gases from diffusing onto the top surface of the fourth plate 416 under the substrate 417, which prevents deformities (e.g., fluorination) on the top surface of the fourth plate 416 that can be otherwise caused by the diffusion.

A third gas (e.g., an inert gas or hydrogen gas), which is also called an edge gas, is supplied through the third plenum (i.e., the pocket edge gas plenum) 466. The third gas further improves edge uniformity along the edge (e.g., OD and bevel edges) of the substrate 417 during substrate processing. The second gas can also be heated to improve temperature uniformity and reduce cold spots in regions of the substrate 417 that lie directly above the pockets 430.

To process the substrate 417, the substrate is arranged on the pedestal 400 in a processing chamber (see FIG. 26). Before processing the substrate 417, the substrate 417 is clamped to the top surface of the fourth plate 416 of the pedestal 400. To clamp the substrate 417, a vacuum pump (shown in FIG. 26) evacuates gases in the processing chamber by removing gases from the processing chamber though the fourth plenum (i.e., the vacuum clamping plenum 472 described above).

Due to the disjoint structures of the first, second, third, and fourth plenums 442, 450, 466, 472 as described above, the gases flowing through each of the first, second, third, and fourth plenums 442, 450, 466, 472 do not mix with each other. The first gas flowing through the first plenum 442 does not mix the gases flowing through each of the second, third, and fourth plenums 450, 466, 472. The second gas flowing through the second plenum 450 does not mix the gases flowing through each of the first, third, and fourth plenums 442, 466, 472. The third gas flowing through the third plenum 466 does not mix the gases flowing through each of the first, second, and fourth plenums 442, 450, 472. The gases flowing through the fourth plenum 472 also do not mix the gases flowing through each of the first, second, and third plenums 442, 450, 466.

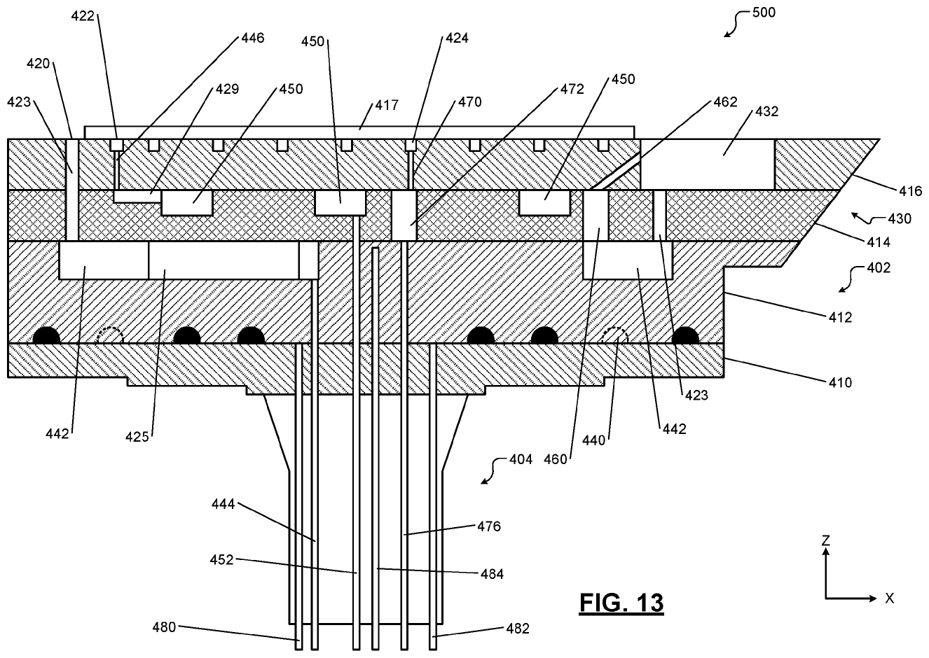

FIGS. 6A-6C show a top view of the pedestal 400. All grooves in FIGS. 6A-9 are shown as single lines for illustrative convenience. Each circular groove (e.g., the edge gas groove 420, the purge gas groove 422, and concentric clamping grooves 424) comprises a circular groove disposed between two concentric circles (e.g., see FIG. 12) with an inner circle defining an inner diameter (ID) of the circular groove and an outer circle defining an outer diameter (OD) of the circular groove. Each linear groove (e.g., radial clamping grooves 424 and linear or spoke-like grooves shown in FIGS. 7-9) comprises a groove disposed between two parallel lines extending together (e.g., see FIG. 11A). In the description of FIGS. 6A-25B, elements shown with the same reference numerals as in FIGS. 4 and 5 that are already described with reference to FIGS. 4 and 5 are not described again for brevity.

FIG. 6A shows a top view (i.e., the top surface) of the fourth plate 416 of the pedestal 400. Specifically, the layout of the grooves 420, 422, 424 on the top surface of the fourth plate 416 is shown. The diameters of the grooves 420, 422, 424 are already described above with reference to FIG. 4A and are therefore not described again for brevity. The clamping grooves 424 near the center region 419 of the top surface of the fourth plate 416 identified by a dotted rectangle are shown in detail in FIGS. 11A-11C. The through holes 470 in the clamping grooves 424 near the center region of the top surface of the fourth plate 416 are shown in FIGS. 6B, 6C, and 11A.

In FIG. 6A, to reduce cold spots on the substrate 417 due to the pockets 430, the radially inner ends of the slots 432 are recessed radially outwards. The purge gas groove 422 and the outermost circular clamping groove 424 comprise radially inward rounded portions 434-1, 434-2 that lie opposite to the radially inner ends of the slots 432. The ID of the edge gas groove 420 is increased to reduce overhang of the substrate 417 on the slots 432 in the pockets 430, which improves nonuniformity at substrate edges. The edge gas groove 420 intersects the radially inner ends of the slots 432. At least one of the through holes 423 in the edge gas groove 420 lies in the radially inner ends of the slots 432 (more clearly seen in FIG. 9).

FIG. 6B shows a bottom view (i.e., the bottom surface) of the fourth plate 416. The through holes 446 of the purge gas plenum (shown at 450 in FIG. 5) and the angular holes 462 of the pocket edge gas plenum (shown at 466 in FIG. 5) are visible on the bottom surface of the fourth plate 416. The through holes 470 of the vacuum clamping plenum 472 are also visible on the bottom surface of the fourth plate 416. The through holes 470 are shown in further detail in FIG. 6C.

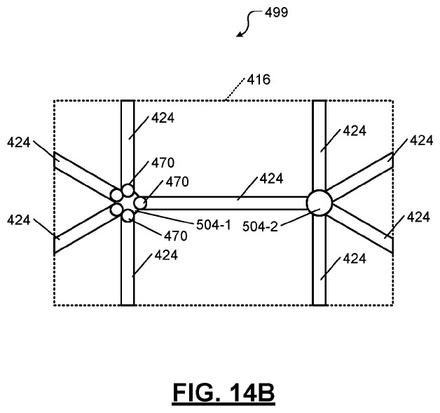

Instead of a single set of through holes formed in a cutout on the top surface of the fourth plate 416 (see FIG. 14B), which can cause cold spots on the substrate 417 in the region that lies above the cutout, the fourth plate 416 comprises at least two sets of through holes 470 as shown in FIG. 6C. The through holes 470 are disposed directly in the clamping grooves 424 instead of in a cutout. Eliminating the cutout eliminates corresponding cold spots. The layout of the through holes 470 within the corresponding clamping grooves 424 and other features such as the width, depth, and rounding of the clamping grooves 424 are shown and described in further detail with reference to FIGS. 11A-11C below.

FIG. 7 shows a top view (i.e., the top surface) of the second plate 412 of the pedestal 400. The second plate 412 comprises five through holes 490, 492, 494, 496, 498 through which five conduits 444, 452, 468, 476, 484 (see FIG. 5) pass, respectively. The edge gas plenum (shown at 442 in FIG. 5) is formed by an annular groove 421 and a plurality of radial grooves 425 in the top surface of the second plate 412. An ID of the annular groove 421 is equal to the diameter of the fifth plate 418. The fifth plate 418 rests on top of the ID of the annular groove 421 and covers the radial grooves 425. The radial grooves 425 connect the through hole 490 to the annular groove 421. The edge gas flows from the conduit 444, via the through hole 490, through the radial grooves 425, through the annular groove 421, via the through holes 423 (shown in FIG. 5) into the edge gas groove 420 on the top surface of the fourth plate 416.

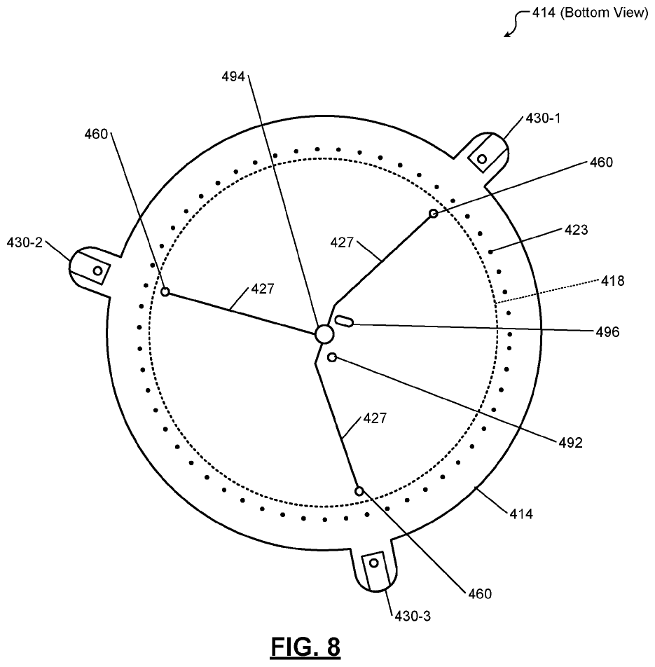

FIG. 8 shows a bottom view (i.e., the bottom surface) of the third plate 414. The bottom surface of third plate 414 comprises three holes 492, 494, 496 through which three conduits 452, 468, 476 (see FIG. 5) pass, respectively. The pocket edge gas plenum (shown at 466 in FIG. 5) is formed by a plurality of radial grooves 427 and the through holes 460, which connect to the angular holes 462 in the fourth plate 416 (see FIG. 5). The radial grooves 427 connect the hole 494 to the through holes 460.

The diameter of the fifth plate 418 is greater than a diameter of pitch circle of the through holes 460 (i.e., the circle on which the through holes 460 lie) and less than the ID of the edge gas groove 420 (see FIG. 5) in which the through holes 423 lie. Accordingly, the top surface of the fifth plate 418 completely or entirely covers the pocket edge gas plenum 466. Thus, the fifth plate 418 separates the pocket edge gas plenum 466 from the edge gas plenum 442 formed in the second plate 412 as shown and described with reference to FIG. 7 above. The edge gas flows from the conduit 468, through the hole 494, through the radial grooves 427, via the through holes 460, through the angular holes 462 (see FIG. 5) into the pockets 430.

FIG. 9 shows a top view (i.e., the top surface) of the third plate 414. The top surface of third plate 414 comprises the holes 492, 496 through which the conduits 452, 476 pass, respectively. The purge gas plenum (shown at 450 in FIG. 5) is formed by a first plurality of radial grooves 433, and an annular groove 431, a second plurality of radial grooves 429. The second plurality of radial grooves 429 comprises greater number of grooves than the first plurality of radial grooves 433. The first plurality of radial grooves 433 connect the hole 492 to the annular groove 431. First ends of the second plurality of radial grooves 429 are connected to the annular groove 431. Second ends of the second plurality of radial grooves 429 are connected to the through holes 446 in the fourth plate 416 (see FIG. 5). The purge gas flows from the conduit 444, through the hole 492, through the first plurality of radial grooves 433, through the annular groove 431, through the second plurality of radial grooves 429, via the through holes 446 (shown in FIG. 5) into the purge gas groove 422 on the top surface of the fourth plate 416.

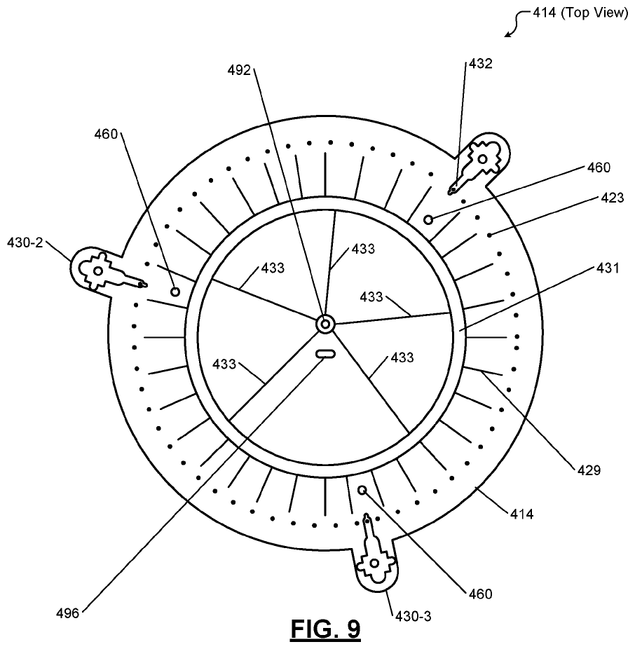

FIG. 10 shows top and bottom views of the fifth plate 418, which are identical. The fifth plate 418 comprises four through holes 492, 494, 496, 498 through which four conduits 452, 468, 476, 484 (see FIG. 5) pass, respectively. In some examples, the temperature sensor may be embedded in the fifth plate 418, in which case element 498 may not be a hole partially drilled into the bottom surface of the fifth plate 418, and the conduit 484 may terminate into the partially drilled hole 498 in the fifth plate 418.

The first plate 410 comprises seven through holes (see FIG. 5). The conduits 444, 452, 468, 476, 480, 482, 484 pass via the through holes in the first plate 410 and through the other plates as described above. The conduit 476 passes via the first plate 410, the through holes 496 in the second and fifth plates 412, 418 and is connected to the through hole 472 in the third plate 414, which in turn is connected via the through holes 470 in the fourth plate 416 to the clamping grooves 424. The vacuum pump (shown in FIG. 26) evacuates gases in the processing chamber by removing gases from the processing chamber though the clamping grooves 424, the through holes 470, the through hole 472, and the conduit 476.

FIGS. 11A-11D show the clamping grooves 424 and the through holes 470 in the clamping grooves in further detail. As described above with reference to FIGS. 6A-6C and as shown in FIG. 11A, the through holes 470 are not located in a cutout formed at the intersection of the radial clamping grooves 424 near the center region of the top surface of the fourth plate 416, an example of which is shown FIG. 14B. Instead, the through holes 490 are disposed in the radial clamping grooves 424 at the intersection of the radial clamping grooves 424 near the center region of the top surface of the fourth plate 416 as shown in FIGS. 6C and 11A.

Further, the through holes 470 are disposed in the radial clamping grooves 424 in multiple rows as shown in FIGS. 6C and 11A (e.g., two rows are shown, but more rows can be added). Each row of the through holes 470 lies on a circle. Thus, the rows of the through holes 470 lie on respective concentric circles. The through holes 490 are located at the intersection of the radial clamping grooves 424 near the center region of the top surface of the fourth plate 416 since the conduit 476 is connected to the through holes 470 via the through hole 472 in the third plate 414 located below the through holes 470 (see FIG. 5). The through holes 470 are not located in any of the clamping grooves 424 other than those shown in FIG. 11A.

FIG. 11B shows that the width w of the clamping grooves 424 (both radial and circular clamping grooves 424 shown in FIG. 6A) is less than the depth d of the clamping grooves 424 (both radial and circular clamping grooves 424 shown in FIG. 6A). The narrower width of the clamping grooves 424 reduces the cold spots on the substrate 417 that can be caused by the clamping grooves 424. The depth of the clamping grooves 424 allows disposing multiple rows the through holes 470 in the clamping grooves 424. The through holes 470 disposed in the clamping grooves 424 as shown in FIGS. 6C and 11A are smaller in diameter but more in number than the through holes 470 disposed in a circular cutout shown in FIG. 14B. Thus, the clamping force provided by the through holes 470 disposed in the clamping grooves 424 as shown in FIGS. 6C and 11A is not reduced as compared to that provided by the through holes 470 disposed in a circular cutout shown in FIG. 14B. Rather, the clamping force can be increased by adding more rows of the through holes 470. Further, by eliminating the cutout to dispose the through holes 470 and by reducing the width of the clamping grooves, the cold spots on the substrate 417 are minimized.

FIG. 11C shows that the clamping grooves 424 (both radial and circular clamping grooves 424 shown in FIG. 6A) are also rounded at outer edges as shown at 477. The rounding of the clamping grooves 424 provides additional advantages. As shown in FIG. 11D, when process gases diffuse under the substrate 417, material produced by chemical reactions between the diffused process gases, which comprise corrosive halogens, for example, and the metallic material the top surface of the fourth plate 416 form deposits that build up over time as shown at 478. If the clamping grooves 424 are not rounded as shown in FIG. 11C, the buildup grows above the plane of the top surface of the fourth plate 416 as shown at 478. Due to the growth of the buildup, a gap exists between the bottom surface of the substrate 417 and the top surface of the fourth plate 416 as shown at 481. The gap allows more process gases to diffuse under the substrate 417, which in turn causes more material to deposit and buildup, which further increases the gap between the bottom surface of the substrate 417 and the top surface of the fourth plate 416. Accordingly, the substrate 417 cannot be properly clamped to the top surface of the fourth plate 416, which causes process nonuniformities and temperature nonuniformities in the substrate 417.

Instead, when the clamping grooves 424 are rounded as shown in FIG. 11C, when process gases diffuse under the substrate 417, the buildup grows below the plane of the top surface of the fourth plate 416 as shown at 483 in FIG. 11E. Due to the growth of the buildup below the plane of the top surface of the fourth plate 416, a gap exists between the buildup and the top surface of the fourth plate 416 as shown at 485 in FIG. 11E. Due to the gap between the buildup and the top surface of the fourth plate 416, the bottom surface of the substrate 417 can contact the top surface of the fourth plate 416, and the substrate 417 can be properly clamped to the top surface of the fourth plate 416, which improves process uniformities and temperature uniformities in the substrate 417.

In some examples, the radius of the rounded edges of the clamping grooves 424 as shown at 477 can be up to 0.04″. Also, this larger radius helps in preventing process variations due to surface irregularities caused by excessive fluorination (corrosions) of the top surface of the fourth plate 416 of the pedestal 400.

FIG. 12 shows the spacing between the edge gas groove 420, and the purge gas groove 422, and the radially inner ends of the pocket 430 and the protrusion 436 of the carrier ring and substrate holder assembly 438 disposed in the slot 432 of the pocket 430. Specifically, the ID of the edge gas groove 420 is increased to minimize substrate overhang as described above. Further, the slot 432 of the pocket 430 and the protrusion 436 of the carrier ring and substrate holder assembly 438 are recessed radially outwards to minimize the cold spots that can be caused by the pockets 430 as described above. Specifically, the inner ends of the pocket 430 and the protrusion 436 of the carrier ring and substrate holder assembly 438 are closer to the ID of the edge gas groove 420 than to the OD of the purge gas groove 422.

For example, a radial distance between a radially inner edge of the slot 432 and the ID of the edge gas groove 420 is d1. A radial distance between a radially inner edge of the protrusion 436 and the ID of the edge gas groove 420 is d2. A radial distance between the radially inner edge of the slot 432 and the OD of the purge gas groove 422 is d3. A radial distance between the radially inner edge of the protrusion 436 and the OD of the purge gas groove 422 is d4. d1<d3, and d2<d4. Thus, the inner ends of the pocket 430 and the protrusion 436 of the carrier ring and substrate holder assembly 438 are closer to the ID of the edge gas groove 420 than to the OD of the purge gas groove 422.

FIGS. 13, 14A, and 14B show another example of a pedestal 500. FIG. 13 shows a cross-sectional view of the pedestal 500. The pedestal 500 is identical to the pedestal 400 shown in FIGS. 4-12 except for the following differences. Therefore, except for the following differences, other elements of the pedestal 500 are not described again for brevity.

The pedestal 500 differs from the pedestal 400 mainly in that unlike the pedestal 400, where the edge gas plenum 442 and the pocket edge gas plenum 466 are disjoint, the edge gas plenum 442 and the pocket edge gas plenum 466 are not disjoint in the pedestal 500. Instead, the edge gas plenum 442 and the pocket edge gas plenum 466 are in fluid communication with each other and is a single, unified, or shared plenum in the pedestal 500. Accordingly, the pedestal 500 does not comprise the fifth plate 418, which separates the edge gas plenum 442 and the pocket edge gas plenum 466 in the pedestal 400 as shown in FIG. 5. Therefore, in the pedestal 500, the bottom surface of the third plate 414 does not comprise the pocket edge gas plenum 466 and is flat. The pedestal 500 also does not comprise the conduit 468, which is used to separately supply the edge gas to the pocket edge gas plenum 466 in the pedestal 400 as shown in FIG. 5. Instead, in the pedestal 500, the conduit 444 supplies the edge gas both to the edge gas groove 420 via the through holes 423 and to the pockets 430 via the angular holes 462.

Further, in the pedestal 500, in some examples, the heater coil 440 can comprise three or more turns as shown in FIG. 5. In the example shown in FIG. 13, the heater coil 440 with additional (i.e., more than three) turns is optional as indicated by showing a fourth coil using dotted lines. Accordingly, as shown in FIG. 13, the pedestal 500 comprises the heater coil 440 with three turns, an example of which is shown at 440-1 in FIG. 21A. In some examples, the pedestal 500 can comprise the heater coil 440 with four turns, an example of which is shown at 440-2 in FIG. 21B. The heater coils 440-1 and 440-2 are collectively and generally referred to as the heater coil 400.

FIG. 14A shows a top view of the fourth plate 416 of the pedestal 500. The top view of the fourth plate 416 of the pedestal 500 is identical to the top view of the fourth plate 416 of the pedestal 400 except for the following difference. Unlike the fourth plate 416 of the pedestal 400, the fourth plate 416 of the pedestal 500 further comprises ceramic springs shown at 502-1, 502-2, 503-2 (collectively called the springs 502). The ceramic springs 502 are disposed around the circumference of the middle circular clamping groove 424 as shown. Similar to the pockets 430, the ceramic springs are arranged 120 degrees apart from each other. In some examples, the ceramic springs 502 radially align with the pockets 430 as shown although the ceramic springs 502 can be arranged differently than shown. In some examples, the ceramic springs 502 can be omitted in the pedestal 500 since cold spots can be caused by the ceramic springs 502 in the substrate 417.

FIG. 14B shows another feature of the pedestal 500 that is different than the pedestal 400. Unlike the pedestal 400, where the fourth plate 416 does not comprise the circular cutouts for the through holes 470 as shown in FIGS. 6C and 11A, the fourth plate 416 of the pedestal 500 comprises the circular cutouts shown at 504-1, 504-2 (collectively called the circular cutouts 504). An expanded view of a center portion 499 of the fourth plate 416 is shown in FIG. 14B. In the cutout 504-1, a single set of the through holes 470 are arranged along the circumference of the cutout 504-1. Alternatively, the through holes 470 can be arranged within the circumference of the cutout 504-1. In some examples, the circular cutouts 504 can be omitted in the pedestal 500 since cold spots can be caused by the circular cutouts 504 in the substrate 417.

In some examples, the pedestal 500 can comprise any combination of the following features along with either the shared plenum (without the fifth plate 418) for supplying the edge gas to the edge gas groove 420 via the through holes 423 and to the pockets 430 via the angular holes 462, or the disjoint plenums (with the fifth plate 418) for supplying the edge gas to the edge gas groove 420 via the through holes 423 and to the pockets 430 via the angular holes 462: the heater coils 440 shown in FIGS. 21A or 21B, the ceramic springs 502 or no ceramic springs 502, the circular cutouts 504 with a single set of the through holes 470 as shown in FIG. 14B or multiple sets of the through holes 470 without the circular cutouts 504 as shown in FIGS. 6C and 11A, and unrounded or rounded clamping grooves 424 shown in FIGS. 11A-11E.

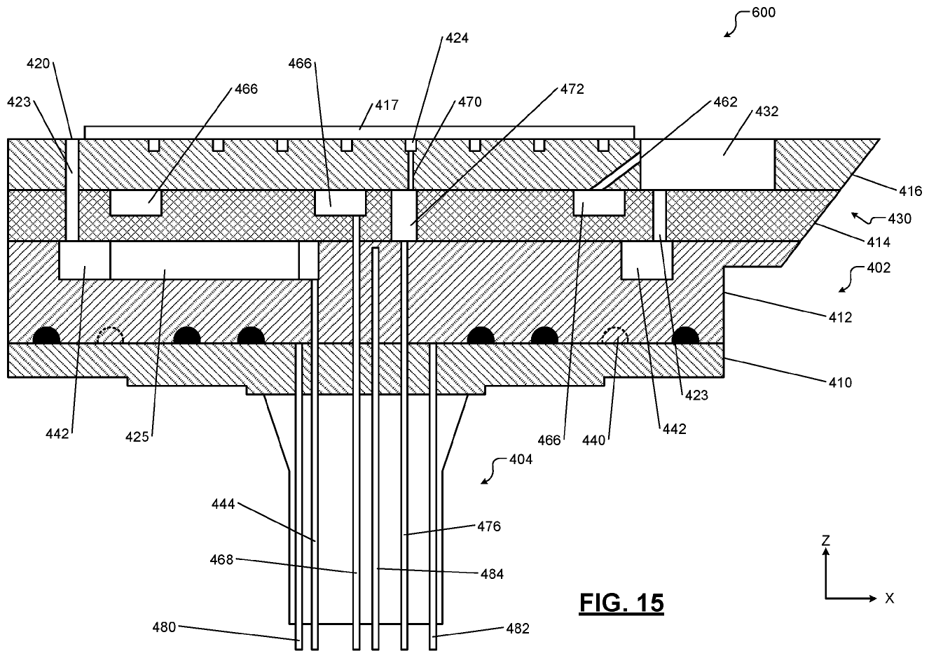

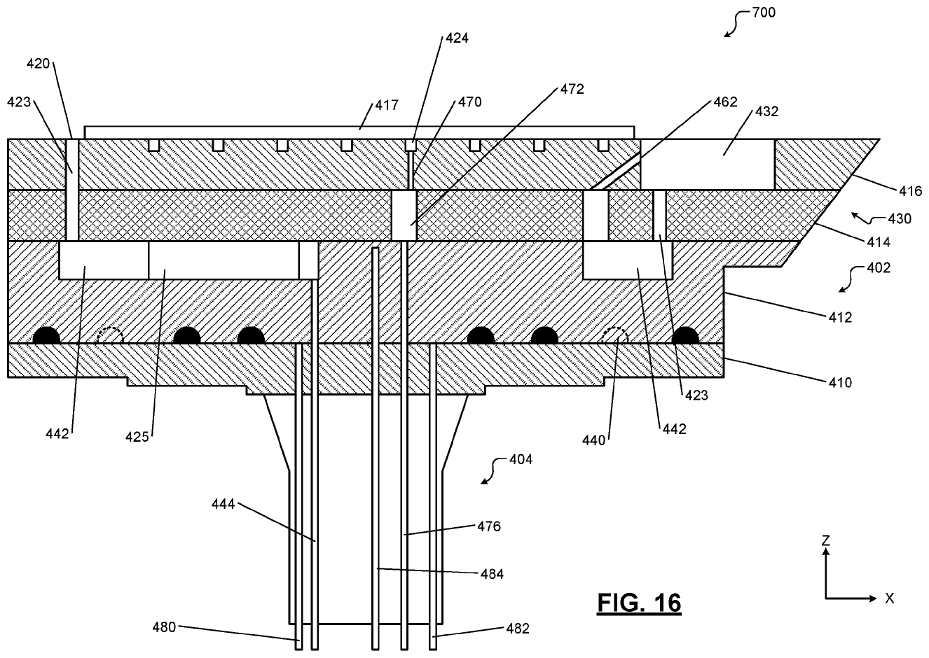

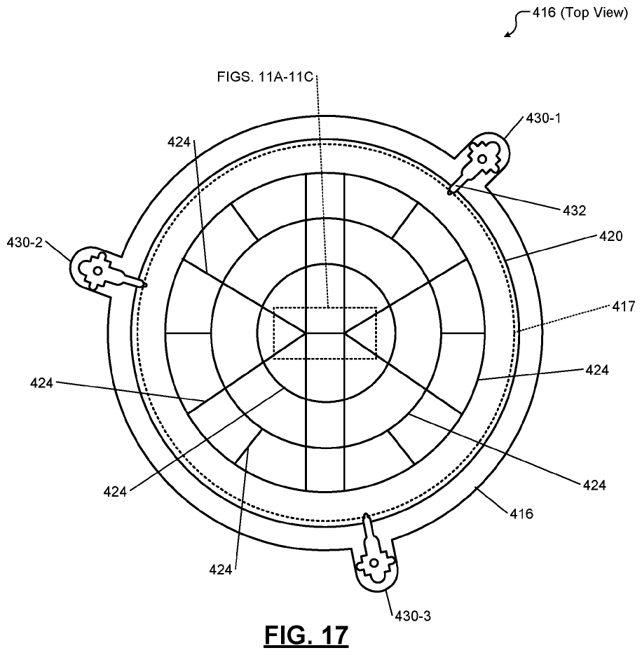

FIGS. 15-17 show additional examples of pedestals 600 and 700. FIGS. 15 and 16 show cross-sectional views of the pedestals 600 and 700, respectively. The top view of the fourth plate 416 for both the pedestals 600 and 700 is shown in FIG. 17. The pedestals 600 and 700 can have the same or similar features as the pedestal 400 described and shown and described with reference to FIGS. 4-12, except for the following differences described below. Therefore, except for the following differences, other elements of the pedestals 600 and 700 are not described again for brevity.

In FIG. 15, the pedestal 600 differs from the pedestal 400 mainly in that unlike the pedestal 400, the pedestal 600 does not supply the purge gas through the purge gas groove 422. Instead, the purge gas plenum 450 is utilized to supply the edge gas to the pockets 430, which operation is performed using the pocket edge gas plenum 466 in the pedestal 400 as shown in FIG. 5. Accordingly, the pedestal 600 does not comprise corresponding elements 422, 446, 429, and 452 of the pedestal 400 described and shown with reference to FIG. 5. The pocket edge gas plenum 466 shown in FIG. 15 is the same as the purge gas plenum 450 shown in FIG. 5 without the elements 422, 446, 429, and 452 of the pedestal 400 shown in FIG. 5 and is further modified as follows to operate as the pocket edge gas plenum 466.

Specifically, in the pedestal 600, the pocket edge gas plenum 466 (i.e., the purge gas plenum 450 shown in FIG. 5 without the elements 422, 446, 429, and 452 of the pedestal 400 shown in FIG. 5) is modified to operate as the pocket edge gas plenum 466 of the pedestal 400 shown in FIG. 5 as follows. In the pedestal 600, the conduit 468 extends through the first and second plates 410, 412 as in the pedestal 400 shown in FIG. 5, and further extends partially through the third plate 414 as shown in FIG. 15. The conduit 468 connects to what is the purge gas plenum 450 in the pedestal 400 shown in FIG. 5, which is the pocket edge gas plenum 466 in the pedestal 600. Therefore, in the pedestal 600, the pocket edge gas plenum 466 and the through hole 460 as shown in FIG. 5 are eliminated, and instead, the purge gas plenum 450 shown in FIG. 5, which is the pocket edge gas plenum 466 in FIG. 15, is connected to the angular holes 462 and supplies the edge gas to the pockets 430 in the pedestal 600 as shown in FIG. 15. Since the pocket edge gas plenum 466 and the through hole 460 as shown in FIG. 5 are eliminated in FIG. 15, in the pedestal 600 shown in FIG. 15, the pedestal 600 also does not comprise the fifth plate 418, and the bottom surface of the third plate 414 is flat.

Thus, the pedestal 600 does not comprise the pocket edge gas plenum 466 of the pedestal 400 shown in FIG. 5 but instead the purge gas plenum 450 shown in FIG. 5 is modified as described above and is utilized as the pocket edge gas plenum 466 in the pedestal 600 as shown in FIG. 15 and as described above. As such, the pocket edge gas plenum 466 of the pedestal 600 can also be called the pocket edge gas plenum 466/450 or the pocket edge gas plenum 466′/450′, where “′” indicates the modifications made to the plenums 450 and 466 in the pedestal relative to the pedestal 400 as shown in FIG. 15 and as described above.

Further, in the pedestal 600, in some examples, the heater coil 440 can comprise three or more turns as shown in FIG. 5. In the example shown in FIG. 15, the heater coil 440 with additional (i.e., more than three) turns is optional as indicated by showing a fourth coil using dotted lines. Accordingly, as shown in FIG. 15, the pedestal 600 comprises the heater coil 440 with three turns, an example of which is shown in FIG. 21A. In some examples, the pedestal 600 can comprise the heater coil 440 with four turns, an example of which is shown in FIG. 21B.

In FIG. 16, the pedestal 700 differs from the pedestal 400 mainly in that unlike the pedestal 400, where the edge gas plenum 442 and the pocket edge gas plenum 466 are disjoint, the edge gas plenum 442 and the pocket edge gas plenum 466 are in fluid communication with each other and is a single, unified, or shared edge gas plenum 442 in the pedestal 700. Accordingly, the pedestal 700 does not comprise the fifth plate 418, which separates the disjoint edge gas plenum 442 and the pocket edge gas plenum 466 in the pedestal 400 as shown in FIG. 5. Therefore, in the pedestal 700, the bottom surface of the third plate 414 does not comprise the pocket edge gas plenum 466 and is flat. The pedestal 700 also does not comprise the conduit 468, which is used to separately supply the edge gas to the pocket edge gas plenum 466 in the pedestal 400 as shown in FIG. 5. Instead, in the pedestal 700, the conduit 444 supplies the edge gas both to the edge gas groove 420 via the through holes 423 and to the pockets 430 via the angular holes 462.

Additionally, the pedestal 700 differs from the pedestal 400 mainly in that unlike the pedestal 400, the pedestal 700 does not comprise the purge gas plenum 450 to supply the purge gas through the purge gas groove 422. Accordingly, the pedestal 700 also does not comprise the elements 422, 446, 429, 433, 450, and 452 of the pedestal 400 shown in FIG. 5. Further, in the pedestal 700, since the top surface of the third plate 414 does not comprise the purge gas plenum 450, the top surface of the third plate 414 is also flat.

Further, in the pedestal 700, in some examples, the heater coil 440 can comprise three or more turns as shown in FIG. 5. In the example shown in FIG. 16, the heater coil 440 with additional (i.e., more than three) turns is optional as indicated by showing a fourth coil using dotted lines. Accordingly, as shown in FIG. 16, the pedestal 700 comprises the heater coil 440 with three turns, an example of which is shown in FIG. 21A. In some example, the pedestal 700 can comprise the heater coil 440 with four turns, an example of which is shown in FIG. 21B.

FIG. 17 shows the top view of the fourth plate 416 for both the pedestals 600 and 700 shown in FIGS. 15 and 16, respectively. The top view of the fourth plate 416 for both the pedestals 600 and 700 is identical to the top view of the fourth plate 416 of the pedestal 400 shown in FIGS. 6A-6C except for the following differences. The fourth plate 416 of the pedestals 600 and 700 does not comprise the purge gas groove 422 and corresponding through holes 446. Additionally, the edge gas groove 420 and the outermost circular clamping groove 424 do not comprise the rounded portions 434-1, 434-2 that lie opposite to the radially inner ends of the slots 432.

While the through holes 470 in the fourth plate 416 for both the pedestals 600 and 700 is as shown in FIGS. 11A-11C, in some examples, the through holes 470 can be arranged on the fourth plate 416 for both the pedestals 600 and 700 as shown in FIG. 14B. Further, in some examples, the pedestals 600 and 700 can comprise any combination of the following features along with no purge gas plenum 450 and either the shared plenum (without the fifth plate 418) for supplying the edge gas to the edge gas groove 420 via the through holes 423 and to the pockets 430 via the angular holes 462, or the disjoint plenums (still without the fifth plate 418 since the purge gas plenum 450 is utilized as the pocket edge gas plenum 466) for supplying the edge gas to the edge gas groove 420 via the through holes 423 and to the pockets 430 via the angular holes 462: the heater coils 440 shown in FIGS. 21A or 21B, the ceramic springs 502 or no ceramic springs 502, the circular cutouts 504 with a single set of the through holes 470 as shown in FIG. 14B or multiple sets of the through holes 470 without the circular cutouts 504 as shown in FIGS. 6C and 11A, and unrounded or rounded clamping grooves 424 shown in FIGS. 11A-11E.

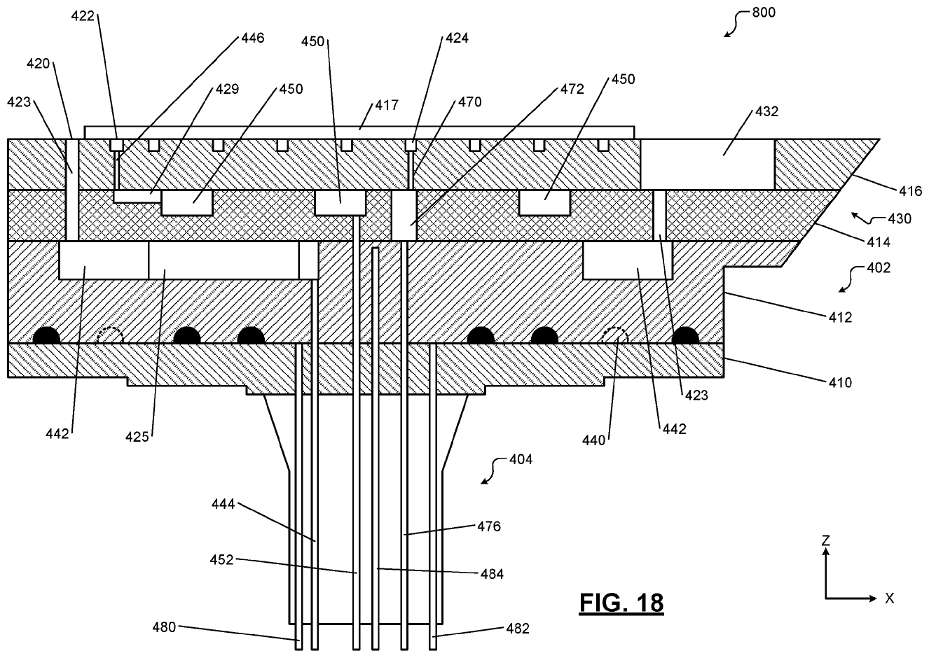

FIG. 18 shows another example of a pedestal 800. The pedestal 800 can have the same or similar features as the pedestal 400 shown and described with reference to FIGS. 4-12, except for the following differences described below. Therefore, except for the following differences, other elements of the pedestal 800 are not described again for brevity.

The pedestal 800 differs from the pedestal 400 mainly in that unlike the pedestal 400, the pedestal 800 does not comprise the pocket edge gas plenum 466. Therefore, in the pedestal 800, the bottom surface of the third plate 414 does not comprise the pocket edge gas plenum 466 and is flat. Further, the pedestal 800 also does not comprise the elements 466, 460, 462, and 468 of the pedestal 400 shown in FIG. 5. Additionally, the pedestal 800 also does not comprise the fifth plate 418, which separates the disjoint edge gas plenum 442 and the pocket edge gas plenum 466 in the pedestal 400 as shown in FIG. 5.

Further, in the pedestal 800, in some examples, the heater coil 440 can comprise more than three turns as shown in FIG. 5. In the example shown in FIG. 18, the heater coil 440 with additional (i.e., more than three) turns is optional as indicated by showing a fourth coil using dotted lines. Accordingly, as shown in FIG. 18, the pedestal 800 comprises the heater coil 440 with three turns, an example of which is shown at 440-1 in FIG. 21A. In some examples, the pedestal 800 can comprise the heater coil 440 with four turns, an example of which is shown at 440-2 in FIG. 21B.

The top view of the fourth plate 416 of the pedestal 800 is identical to the top view of the fourth plate 416 of the pedestal 400 shown in FIG. 6A. In some examples, the pedestal 800 can comprise any combination of the following features: the heater coils 440 shown in FIGS. 21A or 21B, the ceramic springs 502 or no ceramic springs 502, the circular cutouts 504 with a single set of the through holes 470 as shown in FIG. 14B or multiple sets of the through holes 470 without the circular cutouts 504 as shown in FIGS. 6C and 11A, and unrounded or rounded clamping grooves 424 shown in FIGS. 11A-11E.

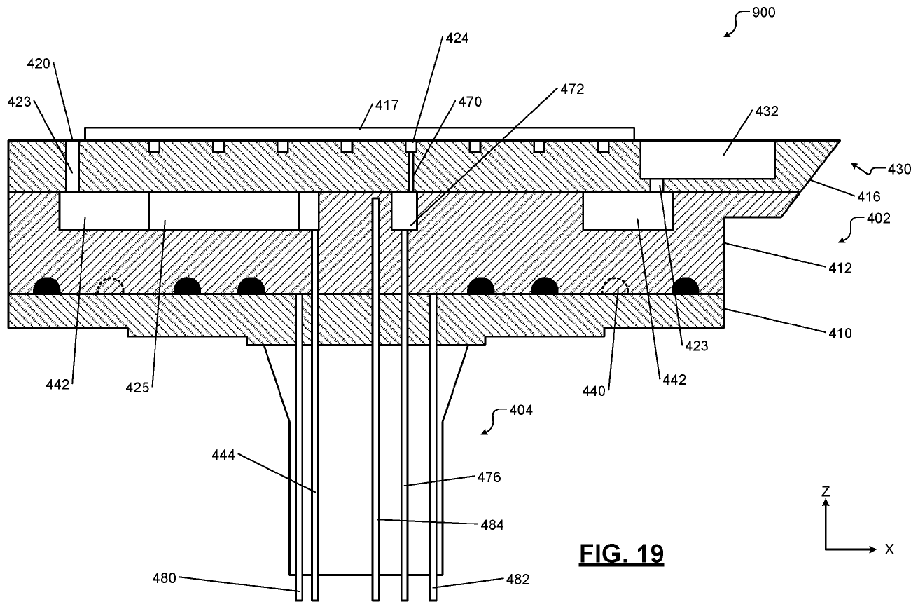

FIG. 19 shows still another example of a pedestal 900. The pedestal 900 can have the same or similar features as the pedestal 400 shown and described with reference to FIGS. 4-12, except for the following differences described below. Therefore, except for the following differences, other elements of the pedestal 900 are not described again for brevity.

The pedestal 900 differs from the pedestal 400 mainly in that unlike the pedestal 400, the pedestal 900 does not comprise the pocket edge gas plenum 466 and the purge gas plenum 450. Therefore, the pedestal 900 does not comprise the third plate 414 and the fifth plate 418. Further, the pedestal 900 also does not comprise the elements 466, 460, 462, and 468 of the pedestal 400 shown in FIG. 5. Additionally, the pedestal 800 also does not have the elements 450, 429, 433, 446, 422, and 452 of the pedestal 400 described and shown with reference to FIG. 5.

Further, in the pedestal 900, in some examples, the heater coil 440 can comprise three or more turns as shown in FIG. 5. In the example shown in FIG. 19, the heater coil 440 with additional (i.e., more than three) turns is optional as indicated by showing a fourth coil using dotted lines. Accordingly, as shown in FIG. 19, the pedestal 900 comprises the heater coil 440 with three turns, an example of which is shown in FIG. 21A. In some examples, the pedestal 900 can comprise the heater coil 440 with four turns, an example of which is shown in FIG. 21B.

The top view of the fourth plate 416 of the pedestal 900 is identical to the top view of the fourth plate 416 of the pedestals 600, 700 shown in FIG. 17. In some examples, the pedestal 900 can comprise any combination of the following features: the heater coils 440 shown in FIGS. 21A or 21B, the ceramic springs 502 or no ceramic springs 502, the circular cutouts 504 with a single set of the through holes 470 as shown in FIG. 14B or multiple sets of the through holes 470 without the circular cutouts 504 as shown in FIGS. 6C and 11A, and unrounded or rounded clamping grooves 424 shown in FIGS. 11A-11E.

FIGS. 20A and 20B show a side front view of the pockets 430. FIG. 20A shows the pockets 430 for the pedestals 400, 500, 600, 700, and 800. FIG. 20B shows the pockets 430 for the pedestal 900. In FIGS. 20A and 20B, locations where the plates are brazed together are identified as brazing interfaces 1000.

As described above, each of the pockets 430 comprise a slot 1002 in which a nut plate and a washer (both shown in FIG. 22A) are arranged. A fastener (shown in FIG. 22A) is inserted through a hole 1004 in a wheel block assembly disposed in the pocket 430 (shown in FIG. 22A) to secure the wheel block assembly to the pedestal by engaging with the nut plate in the slot 1002 in the pocket 430.

As shown in FIGS. 20A and 20B, in each of the pockets 430, the slot 1002 is formed in a radially outer wall of the pocket 430. The slot 1002 is located away from the brazing interfaces 1000 of a plurality of the plates 412-416 such that the slot 1002 is not located at any of the brazing interfaces 1000. None of the brazing interfaces 1000 intersects the slot 1002. The slot 1002 does not include any of the brazing interfaces 1000. Instead, the slot 1002 is located between brazing interfaces 1000 of adjacent plates. The slot 1002 is formed entirely within a thickness of one of the plates 412-416. A height of the slot 1002 is less than the thickness of one of the plates 412-416 in which the slot 1002 is formed. Accordingly, a larger surface area of the plates is available for brazing the plates, which results in increased bonding strength between the plates. Further, when the washer expands, the mechanical force from the expansion is less than the bonding force keeping the plates together, which prevents delamination of the pockets 430.

FIGS. 21A and 21B show examples of the heater coil 440. FIG. 21A shows an example of the heater coil 440 with three turns shown at 440-1. FIG. 21B shows an example of the heater coil 440 with four turns shown at 440-4. The heater coils 440-1 and 440-2 are collectively and generally referred to as the heater coil 440 throughout the present disclosure. In some examples, the heater coil 440 can comprise additional turns. The heater coil comprises first and second ends 1110, 1112 to which the conduits 480, 482 are connected, respectively. Power is supplied to the heater coil 440 through the conduits 480, 482 as described below with reference to FIG. 26. Based on the number of turns of the heater coil 440, the bottom surface of the second plate 412 comprises grooves (not shown) in which the heater coil 440 is disposed.

FIGS. 22A and 22B show examples of the wheel block assembly 1050 and the carrier ring and substrate holder assembly 438. In FIG. 22A, the wheel block assembly 1050 is disposed in the slot 432 of the pocket 430. The wheel block assembly 1050 comprises wheels 1054-1, 1054-2. A plurality (e.g., three) of the carrier ring and substrate holder assembly 438 is attached to a bottom surface of a carrier ring 1051. When the carrier ring 1051 carrying the substrate 417 (e.g., see FIG. 5) is loaded onto the pedestal, the carrier ring and substrate holder assembly 438 is inserted in the wheel block assembly 1050. The wheels 1054-1, 1054-2 hold the carrier ring and substrate holder assembly 438 in the wheel block assembly 1050.

In FIG. 22B, the carrier ring and substrate holder assembly 438 comprises a substrate holder (also called a contact finger) 437 that extends radially inwards from the pocket 430. The contact finger 437 comprises the protrusion 436 to support the substrate 417 and a centering wheel 439 to center the substrate 417 on the pedestal. The wheel block assembly 1050 is fastened to a nut plate 1058 in the pocket 430 using a fastener 1056 that passes through the hole 1004 in the wheel block assembly 1050. A washer 1060 is used with the fastener 1056 and the nut plate 1058. The nut plate 1058 is inserted into the slot 1002 located at the base of the pocket 430. The location of the slot 1002 and advantages provided by the location of the slot 1002 are already described above with reference to FIGS. 20A and 20B and is therefore not repeated for brevity.

FIGS. 23A-25B show examples of arrangements of the conduits 406 in the stem portion 404 of some of the pedestals described above. FIGS. 23A and 23B show the arrangement of the conduits 444, 452, 468, 476, 480, 482, 484 of the pedestal 400. FIG. 23A shows a cross-sectional view of the stem portion 404 of the pedestal 400 with the conduits in the stem portion 404 of the pedestal 400. FIG. 23B shows a perspective view of the stem portion 404 of the pedestal 400.

In FIGS. 23A and 23B, the conduits 444, 452, 468, 476, 484 are disposed through a narrow opening 1102 at the bottom end of the stem portion 404 of the pedestal 400 as shown. As described below, the heater conduits 480, 482 do not extend through the opening 1102. Instead, only conductors 480-1, 482-1 of the heater coil 440 within the heater conduits 480, 482 extend through the opening 1102. The opening 1102 of the stem portion 404 of the pedestal 400 is the same as the opening 1102 of the stem portion 404 of the pedestal 500 shown in FIGS. 24A and 24B, which uses fewer conduits than the pedestal 400. Accordingly, a greater number of conduits are disposed though the opening 1102 in the stem portion 404 of the pedestal 400 than the number of conduits disposed though the same opening 1102 in the stem portion 404 of the pedestal 500.

In some examples, to accommodate the greater number of conduits within the opening 1102 in the stem portion 404 of the pedestal 400 without increasing the size of the opening 1102, the conduits 480, 482 are shorter than the other conduits and do not exit the bottom end of the stem portion 404 through the opening 1102. Instead of the conduits 480, 482, only conductors 480-1, 482-1 of the heater coil 440 (see FIGS. 23A and 23B) within the conduits 480, 482 through which power is supplied to the heater coil 440 exit the bottom end of the stem portion 404 through the opening 1102 and are connected to a power supply. Outside the conduits 480, 482, the conductors 480-1, 482-1 are electrically insulated with an insulating material so as to not cause a short circuit with the stem portion 404 or other components of the substrate processing system. The insulating material can withstand high thermal and mechanical stresses and is also resistant to harsh process chemistries. The stem portion 404 comprises openings 1100 for fasteners (not shown) with which the stem portion 404 is attached to other components of a substrate processing system.

FIGS. 24A and 24B show the arrangement of the conduits 444, 452, 476, 480, 482, 484 of the pedestal 500. FIG. 24A shows a cross-sectional view of the stem portion 404 of the pedestal 500 with the conduits in the stem portion 404 of the pedestal 500. FIG. 24B shows a perspective view of the stem portion 404 of the pedestal 500. The conduits 444, 452, 480, 482, 484, 476 are disposed through the narrow opening (e.g., a cutout) 1102 at the top end of the stem portion 404 of the pedestal 500 as shown. Conductors 480-1, 482-1 of the heater coil 440 through which power is supplied to the heater coil 440 are shown. The stem portion 404 comprises openings 1100 for fasteners (not shown) with which the stem portion 404 is attached to other components of a substrate processing system.

FIGS. 25A and 25B show the arrangement of the conduits 444, 476, 480, 482, 484 of the pedestal 900. FIG. 25A shows a cross-sectional view of the stem portion 404 of the pedestal 900 with the conduits in the stem portion 404 of the pedestal 900. FIG. 25B shows a perspective view of the stem portion 404 of the pedestal 500. The conduits 444, 480, 482, 484, 476 are disposed through the narrow opening (e.g., a cutout) 1102 at the top end of the stem portion 404 of the pedestal 900 as shown. The stem portion 404 comprises openings 1100 for fasteners (not shown) with which the stem portion 404 is attached to other components of a substrate processing system.

FIG. 26 shows an example of a substrate processing system 1200 in which any of the pedestals described above can be used. The substrate processing system 1200 comprises a station (also called a process module) 1212 in which substrates are processed. While only one station 1212 is shown as an example, the substrate processing system 1200 may comprise a plurality of stations 1212. Each station 1212 may use any of the pedestals described above. For example, a substrate may be processed sequentially in the stations 1212. Different processes such as atomic layer deposition (ALD), chemical vapor deposition (CVD), plasma enhanced ALD (PEALD), plasma enhanced CVD (PECVD), and so on may be performed on the substrate in different stations using different pedestals described above.

The station 1212 comprises a pedestal 1214 and a showerhead 1216. The pedestal 1214 can be any pedestal described above. The pedestal 1214 comprises a base portion 1218 (e.g., the base portion 402 described above) and a stem portion 1220 (e.g., the stem portion 404 described above. The stem portion 1220 extends from base portion 1218 and is coupled to the bottom of the station 1212. During processing, a substrate 1224 (e.g., the substrate 417 described above) is arranged on a top surface of the base portion 1218 of the pedestal 1214.

The showerhead 1216 comprises a base portion 1226 and a stem portion 1228. The base portion 1226 of the showerhead 1216 is cylindrical. The stem portion 1228 of the showerhead 1216 extends from the base portion 1226 of the showerhead 1216. The stem portion 1228 of the showerhead 1216 is attached to a top plate of the station 1212. The stem portion 1228 of the showerhead 1216 receives various gases (e.g., process gases, vaporized precursors, purge gases, cleaning gases, etc.) from a gas delivery system 1250 via a manifold 1252. The base portion 1226 of the showerhead 1216 comprises a faceplate comprising through holes or slots (not shown) through which the gases are introduced into the station 1212.

The substrate processing system 1200 comprises the gas delivery system 1250. The gas delivery system 1250 comprises gas sources 1254, valves 1256, and mass flow controllers (MFCs) 1258. The gas sources 1254 supply various gases such as process gases, inert gases (also called purge gases, edge gases, carrier gases), cleaning gases, etc. The valves 1256 are connected to the gas sources 1254 and can be controlled to supply the gases to the MFCs 1258. The MFCs 1258 regulate the flow of gases to the manifold 1252.

Additionally, the substrate processing system 1200 comprises another delivery system configured to deliver vaporized precursors via respective valves, which is collectively shown as vaporized precursors and valves 1251. The vaporized precursors and valves 1251 deliver vaporized precursors to the manifold 1252. The manifold 1252 supplies the gases or gas mixtures to the showerhead 1216.

The substrate processing system 1200 comprises a radio frequency (RF) power supply 1260. When plasma is used, the RF power supply 1260 supplies RF power to the showerhead 1216 during processing of the substrate 1224 and during cleaning of the station 1212 with the pedestal 1214 being grounded or floating. The RF power excites the gases (e.g., process gases, vaporized precursors, cleaning gases) introduced into the station 1212 to generate plasma between the showerhead 1216 and the pedestal 1214. In some examples, the RF power supply 1260 may supply RF power to the pedestal 1214 instead of the showerhead 1216 to generate plasma with the showerhead 1216 being grounded or floating.

The base portion 1218 of the pedestal 1214 comprises a heater 1262 (e.g., the heater coil 440 described above). The heater 1262 heats the base portion 1218 of the pedestal 1214, which in turn heats the substrate 1224. The base portion 1218 of the pedestal 1214 comprises a temperature sensor 1264 (e.g., a thermocouple connected to the conduit 484 as described above) to sense the temperature of the pedestal 1214.

The base portion 1226 of the showerhead 1216 may also comprise a heater (not shown) to heat the gases being introduced into the station 1212. Additionally, the base portion 1226 of the showerhead 1216 may also comprise a temperature sensor 1268 to sense the temperature of the showerhead 1216.

The substrate processing system 1200 comprises another set of valves 1290 connected to the gas sources 1254, MFCs and a pressure controller collectively shown at 1292, and a heater 1294. An edge gas and a purge gas from the gas sources 1254 is introduced into the pedestal 1214 via the valves 1290 (e.g., through the edge gas plenum 442, the pocket edge gas plenum 466, and the purge gas plenum 450 in the pedestal 1214 as described above).

First and second MFCs 1292 control the flow of the edge gas through the edge gas plenum 442 and the pocket edge gas plenum 466, respectively. The pressure controller 1292 controls the pressure at which the purge gas is supplied through the purge gas plenum 450. Specifically, the pressure controller 1292 is set to a pressure higher than the process pressure in the station 1212. This forces the purge gas to flow radially outwards from underneath the substrate 417 towards and into the chamber (i.e., the volume of the station 1212 around the pedestal 1214). The flow of the purge gas prevents diffusion of frontside reactive gases, prevents backside deposition reaction from occurring, and prevents corrosion of the top surface of the top plate 416.

The edge gas flows through the edge gas plenum 442 and the pocket edge gas plenum 466 around the edges of the substrate 1224 to control processing (e.g., deposition, etching) at the edges (bevel) of the substrate 1224 as described above in detail. The purge gas flows through the purge gas plenum 450 under the substrate 1224 to control backside deposition and diffusion of the process gases under the substrate 1224 as described above in detail. The heater 1294 heats the edge gas supplied to the pocket edge gas plenum 466 as described above in detail.

A vacuum pump 1272 is connected to the pedestal 1214 (e.g., to the conduit 476 described above) via another one of the valves 1270. To clamp the substrate 1224, the vacuum pump 1272 creates vacuum on the top surface of the pedestal 1214 by evacuating gases in the station 1212 via the vacuum clamping plenum 472 as described above in detail.

The substrate processing system 1210 comprises a controller 1280. The controller 1280 controls the valves 1256, 1290, and 1270; the MFCs 1258 and 1292 and the pressure controller 1292; the heater 1294 and the heaters in the pedestal 1214 and the showerhead 1216; the RF power supply 1260; and the vacuum pump 1272. The controller 1280 monitors the temperatures of the pedestal 1214 and the showerhead 1216 using the temperature sensors 1264 and 1268 in the pedestal 1214 and the showerhead 1216. The controller 1280 controls the temperatures of the pedestal 1214 and the showerhead 1216 by controlling the heaters in the pedestal 1214 and the showerhead 1216.

Additionally, while not shown, the substrate processing system 1200 may also comprise a cooling system that supplies a coolant to cooling channels in the pedestal 1214 and the showerhead 1216. The controller 1280 controls the supply of the coolant to the cooling channels in the pedestal 1214 and the showerhead 1216 to control the temperatures of the pedestal 1214 and the showerhead 1216.

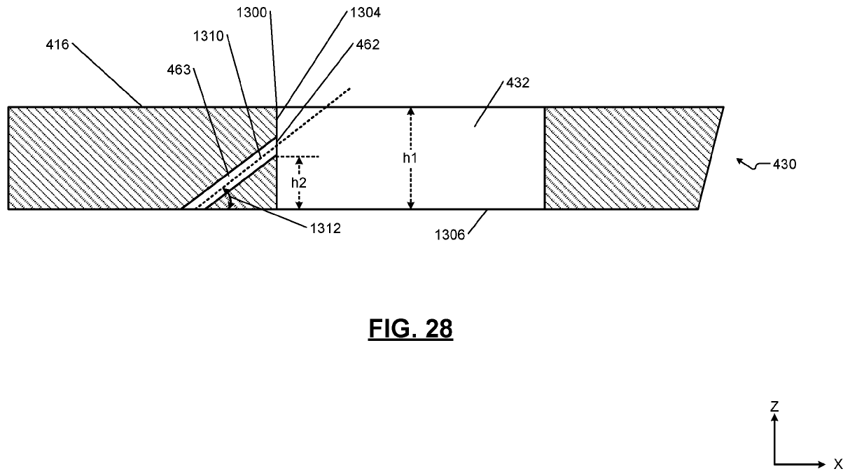

Additional details about the various features of the pedestals, which are shown and described above with reference to FIGS. 1-26, are described below with reference to FIGS. 27 and 28. FIG. 27 shows a top view of the pocket 430. FIG. 28 shows an expanded view of the angular hole 462. Other than the additional details described below, all other details of the features, which are identified by the same reference numerals, are not described again for brevity. The description below applies to all pedestals described above except as otherwise noted.

In FIG. 27, for example, a pedestal described in the embodiments of the current disclosure may have at least three pockets 430 defined along a perimeter of the pedestal. An example of one pocket 430 is shown. Each pocket 430 comprises a narrow portion 1300 and a wide portion 1302. The narrow portion 1300 is located radially inwardly with respect to the wide portion 1302. A tip of the narrow portion 1300 (i.e. an inner tip portion 1301 of the pocket 430) can be the narrowest portion within the narrow portion 1300 of the pocket 430. In some embodiments, the inner tip portion 1301 of the pocket 430 is positioned radially inward from the edge gas groove 420. The wide portion 1302 is located radially outwardly from the narrow portion 1300. The wide portion 1302 is located radially outward from the edge gas groove 420.

In some pedestals shown and described with reference to FIGS. 4A-13 (but not in the pedestals shown and described with reference to FIGS. 15-19), the edge gas groove 420 is located on the top surface of the pedestal as described above with reference to FIGS. 4A-6A. Also as described above, the edge gas groove 420 is concentric with the pedestal. The edge gas groove 430 intersects the narrow portion 1300 of each pocket 430. In some embodiments, at least 30 through holes 423 are within the edge gas groove 420, and at least one through hole 423 is within the narrow portion 1300 of each pocket 430. In one example, the edge gas groove 420 comprises 96 through holes 423. In some examples, the edge gas groove 420 comprises more than 60 through holes 423, more than 80 through holes 423, or more than 90 through holes 423.

In some examples, the through holes 423 can be distributed radially uniformly within the edge gas groove 420. In other examples, the distribution of the through holes 423 within the edge gas groove 420 may not be uniform. For example, a first set of through holes 423 may be closer to one another than the through holes 423 in a second set of through holes 423. The distance between the through holes 423 in the first set may to less than the distance between the through holes 423 in the second set. Thus, the through holes 423 may be grouped in one or more clusters along the edge gas groove 420. As another example, some of the through holes 423 can be closer to an inner wall (i.e., ID) of the edge gas groove 420, while other through holes 423 can be closer to the outer wall (i.e., OD) of the edge gas groove 420.

Having numerous through holes 423 in the edge gas groove 420 can provide several advantages. For example, more through holes 423 can provide more uniform gas delivery at the edge of the substrate 417. Further, more through holes 423 can reduce gap spots around the outer edge portions of the substrate 417. Furthermore, more through holes 423 can provide faster gas delivery to each radial spot. For certain applications, it is preferable to have the number of the through holes 423 to be between 60 to 130, and in some instances, between 85-110. Too many through holes can lead to high manufacturing cost and make consistent hole placement difficult. In some instances, clogging can be an issue when too many through holes 423 are placed within the edge gas groove 420 (or having too many through holes 423 too close together). Because various through holes of the pedestal need to operate together, the number of the through holes 423 in the edge gas groove 420 is calculated and strategically positioned so that the advantages mentioned above can be realized while reducing the potential negative impact.

The outermost (also called the first) circular clamping groove 424 is located radially inward from the edge gas groove 420 on the top surface of the pedestal as described above with reference to FIGS. 4A-6A. Also as described above, the purge gas groove 422 is located radially inward from the edge gas groove 420 and is located between the edge gas groove 420 and the (first) circular clamping groove 424 on the top surface of the pedestal. In some embodiments, about 25-50 through holes 446 are in the purge gas groove 422. In some embodiments, about 30-40 through holes 446 are in the purge gas groove 422. In some embodiments, 35-37 through holes 446 are in the purge gas groove 422. Some of the tradeoffs discussed above with reference to the edge gas groove 420 also apply for the through holes 446. Enough through holes 446 need to be placed to achieve optimal/uniform purge effect underneath the substrate 417.

In FIG. 28, in the pedestals shown in FIGS. 4A-16, at least one angular hole 462 is located within the narrow portion 1300 of each pocket 430. In some examples, not all pockets 430 have an angular hole 462 (e.g., 1 out of 3 pockets 430 has an angular hole 462, or 2 out of 3 pockets 430 have an angular hole 462). In these examples, other pockets 430 may have no hole around the same region or may have a non-angular hole. The narrow portion 1300 is laterally narrow along a plane parallel to the x-axis as seen in FIG. 27. In FIG. 28, a height of the narrow portion 1300 along the z-axis is seen. The at least one angular hole 462 is connected to a gas delivery conduit 463. In some embodiments, the angular hole 462 is located on a sidewall 1304 of the narrow portion 1300 of each pocket 430 that is closest to a center of the pedestal.

Specifically, the angular hole 462 is located on a radially inner sidewall 1304 of the narrow portion 1300 of each pocket 430, where the sidewall 1304 is perpendicular to a bottom surface 1306 of each pocket 430. The angular hole 462 is located above at least 25% of a height h1 of the sidewall 1304 of the narrow portion 1300 of each pocket 430 that is closest to the center of the pedestal. The height h2 at which the angular hole 462 is located on the sidewall 1304 is measured from the bottom surface 1306 of each pocket 430. In some examples, the angular hole 462 is located above at least 50-75% of the height h1 of the sidewall 1304 of the narrow portion 1300 of each pocket 430. In some embodiments, one pocket's angular hole 462 may be at a different height (h2) than the height (h2) of the angular hole 462 at the next pocket 430. The advantages of placing the angular hole 462 at a selected height on the sidewall 1304 are described below.

The gas delivery conduit 463 has a center axis 1310 that is not perpendicular to the side wall 1304 of the narrow portion 1300 of each pocket 430. Perpendicular means forming an angle of 90 degree to a given line, plane, or surface. Instead, the center axis 1310 of the gas delivery conduit 463 forms an acute angle 1312 with the side wall 1304 of the narrow portion 1300 of each pocket 430. In some examples, the angle 1312 is between 20 to 80 degrees. In other examples, the angle 1312 is between 30 to 70 degrees or 40 to 60 degrees, or 45 to 56 degrees. In some embodiments, the gas delivery conduit 463 at one pocket 430 forms an acute angle with the sidewall 1304 that is different than the acute angle formed in another pocket 430. In other words, gas delivery conduits 463 at different pocket 430 may be created with different reference angle.

The height and the angle at which the angular hole 462 opens on the sidewall 1304 can determine the direction, trajectory, and distribution of the gas flowing out of the angular hole 462 into the pocket 430. For example, without the gas flow from the angular hole 462 into the pockets 430, the pocket areas can typically cause cold spots on portions of the substrate 417 that lie above the pocket areas. The gas supplied through the angular holes 462 located at selected height and angle on the sidewall 1304 can reduce or eliminate the cold spots and to improve process uniformity on the substrate 417 at locations of the substrate 417 that lie above the pocket areas. The angle is selected such that the gas flowing out of the angular hole 462 purges the finger area of the pocket 430 effectively and also flows to the substrate 417, which improves uniformity. The height and angle are also selected such that some amount of material is present above the angular hole 462 (between the top of the angular hole 462 and the top surface of the pedestal) for structural integrity.

Further, the gas supplied through the angular holes 462 located at selected height and angle on the sidewall 1304 can be heated as described above with reference to FIG. 26 to locally increase the temperature of the substrate 417 in the regions directly above the pockets 430, which improves temperature nonuniformity and reduces cold spots on the substrate 417 in the regions directly above the pockets 430. In some embodiments, the angle of the angular holes 462 is set to be between 45 to 56 degrees for each pocket to achieve the desirable uniformity.

The purge gas groove 422 also includes through holes 446 as described above with reference to FIGS. 4A-6A. Also as described above, the purge gas groove 422 and the first clamping groove 424 include the radially inward rounded portions 434-1, 434-2 (shown and described with reference to FIG. 6A) that lie opposite to radially inner ends (i.e., the narrow portions 1300) of the respective pockets 430.

In addition, as described above with reference to FIGS. 4A-6A, the pedestals further comprise a plurality of clamping grooves 424 located radially inward from the first clamping groove 424. The plurality of clamping grooves 424 comprise a plurality of radial clamping grooves and one or more of concentric clamping grooves (e.g., see FIG. 6A). At least one of the plurality of radial clamping grooves intersects with the one or more of concentric clamping grooves and the first clamping groove. The plurality of radial clamping grooves proximate to a center portion 419 (see FIGS. 6A and 11A) of the pedestal comprises the plurality through holes 490 arranged in a circular arrangement. The clamping grooves 424 and the through holes 490 are shown and described above in further detail with reference to FIGS. 6A and 11A-11C.

As described with reference to FIGS. 6A and 11A-11C, the plurality of radial clamping grooves 424 proximate to the center portion 419 of the pedestal comprises one or more through holes 490 along each of the plurality of radial clamping grooves 424. In some embodiments, a diameter of the one or more through holes 490 occupies between 65-100% of a width of the respective radial clamping groove 424. In some examples, a diameter of the one or more through holes occupies between 75-95% of a width of the respective radial clamping groove 424. In some examples, all through holes 490 are about (+/−5% in this case) 0.045 to 0.050 inches in diameter. In some examples, all through holes 490 are about 0.60 to 0.65 inches in diameter. In some examples, a set of through holes 490 is about 0.45 to 0.50 inches in diameter, while another set of through holes 490 is about 0.60 to 0.65 inches in diameter. Different diameters of the through holes 490 result in different clamping force. The number of the through holes 490 also result in different clamping force. Therefore, the number and diameters of the through holes 490 can be optimized to provide uniform clamping force to clamp the substrate 417. In embodiments where more than one through holes 490 are in a radial clamping groove, one through hole 490 may be bigger or smaller than the next through hole 490 (size in terms of diameter). In other words, the through holes 490 for clamping need not be of the same size along a radial clamping groove. In some embodiments, the through holes 490 in the same radical clamping groove have the same diameter.

Further, as seen in FIG. 11A, the center portion 419 of the top surface of the pedestal comprises a plurality of intersection points where the plurality of radial clamping grooves 424 intersect. In some examples, the center portion 419 of the top surface of the pedestal comprises two intersection points 471, 473 where five of the plurality of radial clamping grooves 424 intersect.

In some embodiments, the angles between adjacent ones of the plurality of radial clamping grooves 424 branching away from one of the plurality of intersection points 471 are not uniform (i.e., not all are 72 degrees apart). Of the plurality of radial clamping grooves 424 branching away from one of the plurality of intersection points 471, a first groove is ninety degrees apart from a second groove adjacent to the first groove in a clockwise direction and is sixty degrees apart from a third groove in a counterclockwise direction. Further, of the plurality of radial clamping grooves 424 branching away from one of the plurality of intersection points 471, a first groove is ninety degrees apart from a second groove adjacent to the first groove in a clockwise direction and is ninety degrees apart from a third groove in a counterclockwise direction. Furthermore, of the plurality of radial clamping grooves 424 branching away from one of the plurality of intersection points 471, at least two adjacent grooves are less than ninety degrees apart from each other, and at least two adjacent grooves are ninety degrees apart from each other. The unique geometric patterns disclosed herein facilitate clamping uniformity so that the substrate 417 is properly clamped over a desirable region of the pedestal with minimum number of through holes 490. It is not ideal if one region underneath the substrate 417 has a much greater clamping force than another region.

At least one through hole 490 is located in each of the plurality of radial clamping grooves 424 branching away from one of the plurality of intersection points 471. In some examples, when two through holes 490 are located in each of the plurality of radial clamping grooves 424 branching away from one of the plurality of intersection points 471, a first set of the through holes 490 is located in each of the plurality of radial clamping grooves 424 in a first circle having a first radius, and a second set of the through holes 490 is located in each of the plurality of radial clamping grooves in a second circle having a second radius, where the second radius is greater than the first radius. In some examples, the first radius is 25-75% of the second radius. Instead of placing multiple clamping through holes 490 nearby and underneath the substrate's perimeter, the placement of these clamping through holes 490 allows the source of the clamping force to be placed centrally, which reduces the space required underneath the pedestal to run the conduit 476. Although the reach to the substrate perimeter is farther away, the through holes 490 and the clamping grooves 424 are configured to allow uniform clamping force from the center region of the pedestal.

As described above with reference to FIG. 4A onwards, at least one of the three pockets 430 is defined in an ear potion of the pedestal, where the ear portion includes the slot 1002 that is defined on an outer surface of the ear portion, and where the slot 1002 is wholly defined within a single plate as shown and described above with reference to FIGS. 20A and 20B. In some examples, the pedestal further comprises the plurality of ceramic springs 502 disposed on the top surface of the pedestal as shown and described above with reference to FIG. 14A.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the examples is described above as having certain features, any one or more of those features described with respect to any one of the examples of the disclosure can be implemented in and/or combined with features of any of the other examples, even if that combination is not explicitly described. In other words, the described examples are not mutually exclusive, and permutations of one or more examples with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support comprising:
at least three pockets defined along a perimeter of the substrate support, each pocket comprising a narrow portion and a wide portion located radially outward from the narrow portion;
an edge gas groove located on a top surface of the substrate support, the edge gas groove being concentric with the substrate support, the edge gas groove intersecting the narrow portion of each pocket, wherein at least thirty through holes are within the edge gas groove and at least one through hole is within the narrow portion of each pocket; and
a first clamping groove located radially inward from the edge gas groove on the top surface of the substrate support.

2. The substrate support of claim 1, further comprising:
at least one angular hole located within the narrow portion of at least one of the at least three pockets, wherein the at least one angular hole is connected to a gas delivery conduit; and
a purge gas groove located between the edge gas groove and the first clamping groove on the top surface of the substrate support.

3. The substrate support of claim 2, wherein the edge gas groove, the purge gas groove, and the first clamping groove are concentric.

4. The substrate support of claim 2, wherein, for the at least one of the at least three pockets, the angular hole is located on a radially inner sidewall of the narrow portion of the respective pocket, the radially inner sidewall of the narrow portion is a closest pocket surface to a center of the substrate support.

5. The substrate support of claim 4, wherein the radially inner sidewall is perpendicular to a bottom surface of the respective pocket.

6. The substrate support of claim 4, wherein the angular hole is located above at least 25% of a height of the radially inner sidewall of the narrow portion of the respective pocket, wherein the height is measured from a bottom surface of the respective pocket.

7. The substrate support of claim 6, wherein the angular hole is located above at least 50-75% of a height of the radially inner sidewall of the narrow portion of the pocket.

8. The substrate support of claim 4, wherein the gas delivery conduit has a center axis that is not perpendicular to the radially inner sidewall of the narrow portion of the respective pocket.

9. The substrate support of claim 8, wherein a center axis of the gas delivery conduit forms an acute angle with the radially inner sidewall of the narrow portion of the pocket.

10. The substrate support of claim 9, wherein the acute angle is between 20 to 80 degrees.

11. The substrate support of claim 9, wherein the acute angle is between 30 to 70 degrees.

12. The substrate support of claim 9, wherein the acute angle is between 40 to 60 degrees.

13. The substrate support of claim 2, wherein the purge gas groove includes one or more through holes.

14. The substrate support of claim 2, wherein the purge gas groove and the first clamping groove comprise inward rounded portions radially aligned with inner ends of the respective pockets.

15. The substrate support of claim 2, further comprising a plurality of clamping grooves located radially inward from the first clamping groove, the plurality of clamping grooves comprising a plurality of radial clamping grooves and one or more concentric clamping grooves, wherein at least one of the plurality of radial clamping grooves intersects with at least one concentric clamping grooves and the first clamping groove.

16. The substrate support of claim 15, wherein the plurality of radial clamping grooves proximate to a center portion of the substrate support comprises a plurality through holes arranged in a circular arrangement.

17. The substrate support of claim 15, wherein the plurality of radial clamping grooves proximate to a center portion of the substrate support comprises one or more through holes along each of the plurality of radial clamping grooves.

18. The substrate support of claim 17, wherein a diameter of the one or more through holes occupies between 55-90% of a width of the respective radial clamping groove.

19. The substrate support of claim 2, wherein at least one of the three pockets is defined in an ear potion of the substrate support, wherein the ear portion of the substrate support includes a slot that is defined on an outer surface of the ear portion, the slot is wholly defined within a single plate.

20. The substrate support of claim 2, further comprising a plurality of ceramic springs disposed on the top surface of the substrate support.

21. The substrate support of claim 1, further comprising a plurality of clamping grooves located radially inward from the first clamping groove, the plurality of clamping grooves comprising a plurality of radial clamping grooves and one or more concentric clamping grooves, wherein at least one of the plurality of radial clamping grooves intersects with the one or more concentric clamping grooves and the first clamping groove.

22. The substrate support of claim 21, wherein the plurality of radial clamping grooves proximate to a center portion of the substrate support comprises a plurality through holes arranged in a circular arrangement.

23. The substrate support of claim 21, wherein the plurality of radial clamping grooves proximate to a center portion of the substrate support comprises one or more through holes along each of the plurality of radial clamping grooves.

24. The substrate support of claim 23, wherein a diameter of the one or more through holes occupies between 55-90% of a width of the respective radial clamping groove.

25. The substrate support of claim 1, wherein at least one of the three pockets is defined in an ear potion of the substrate support, wherein the ear portion of the substrate support includes a slot that is defined on an outer surface of the ear portion, the slot is wholly defined within a single plate.
